(19) United States
(12) Patent Application Publication
(10) Pub. No.: US 2025/0364490 A1
(43) Pub. Date: Nov. 27, 2025

(54) MULTIPLE NON-ACTIVE DIES IN A MULTI-DIE PACKAGE

(71) Applicant: Taiwan Semiconductor Manufacturing Company. Ltd., Hsinchu (TW)

(72) Inventors: Chia-Kuei HSU, Hsinchu City (TW); Ming-Chih YEW, Hsinchu City (TW); Tsung-Yen LEE, Hemei Township (TW); Shin-Puu JENG, Hsinchu (TW)

(73) Assignee: Taiwan Semiconductor Manufacturing Company. Ltd., Hsinchu (TW)

(21) Appl. No.: 19/292,302

(22) Filed: Aug. 6, 2025

Related U.S. Application Data
(62) Division of application No. 17/813,212, filed on Jul. 18, 2022.
(60) Provisional application No. 63/365,730, filed on Jun. 2, 2022.

(51) Int. Cl. H01L 25/065; H01L 23/00; H01L 23/31; H01L 23/498; H01L 23/538; H01L 25/00

(52) U.S. Cl. CPC H01L 25/0655; H01L 23/3185; H01L 23/49811; H01L 23/5383; H01L 24/16; H01L 25/50; H01L 24/13; H01L 2224/13111; H01L 2224/13116; H01L 2224/13139; H01L 2224/13144; H01L 2224/13147; H01L 2224/13155; H01L 2224/13164; H01L 2224/16227

(57) ABSTRACT

A multi-die package includes a plurality of non-active dies among the IC dies included in the multi-die package. The non-active dies may be included to reduce the amount of encapsulant material and/or an underfill material that is used in the multi-die package, which reduces the amount of CTE mismatch in the multi-die package. Moreover, a plurality of non-active dies may be positioned in an adjacent manner between two or more active IC dies. The use of a plurality of non-active dies in a particular area of the multi-die package increases the quantity of gaps in the multi-die package. The increased quantity of gaps in the multi-die package provides an increased amount of area in the multi-die package for stress and strain absorption, and enables more even distribution of stresses and strains in the multi-die package.

### RELATED APPLICATIONS

This application is a divisional of U.S. patent application Ser. No. 17/813,212, filed Jul. 18, 2022, which claims the benefit of U.S. Patent Application No. 63/365,730, filed Jun. 2, 2022, the contents of which are incorporated herein by reference in their entireties.

### BACKGROUND

A multi-die package may include one or more integrated circuit (IC) dies that are bonded to an interposer. Examples of IC dies include a system-on-chip (SoC) IC die, a dynamic random access memory (DRAM) IC die, a logic IC die, and/or a high bandwidth memory (HBM) IC die, among other examples. An interposer may be used to redistribute ball contact areas from the IC dies to a larger area of the interposer. An interposer may enable three-dimensional (3D) packaging and/or other advanced semiconductor packaging techniques.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A and 2B are diagrams of an example multi-die package described herein.

FIG. 3 is a diagram of an example implementation described herein.

FIGS. 4A and 4B are diagrams of an example device package described herein.

FIGS. 5A and 5B are diagrams of an example implementation described herein.

FIGS. 6A-6E are diagrams of an example implementation described herein.

FIGS. 7A and 7B are diagrams of an example implementation described herein.

FIGS. 8A-8C are diagrams of an example implementation described herein.

FIGS. 9A-9C are diagrams of an example implementation described herein.

FIGS. 10A and 10B are diagrams of an example implementation described herein.

FIG. 11 is a diagram of an example implementation of a multi-die package described herein.

FIGS. 12A and 12B are diagrams of example implementations described herein.

FIG. 13 is a diagram of an example implementation of a multi-die package described herein.

FIG. 14 is a diagram of an example implementation of a device package described herein.

FIG. 15 is a diagram of an example implementation of a device package described herein.

FIG. 16 is a diagram of example components of a device described herein.

FIG. 17 is a flowchart of an example process associated with forming a device package.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In a multi-die package, the gaps between integrated circuit (IC) dies may be filled with an encapsulant material and/or an underfill material. The gaps may provide areas in the multi-die package that absorb stress and strain experienced by the multi-die package. These gaps may experience high magnitudes of stress particularly when a coefficient of thermal expansion (CTE) mismatch occurs in the multi-die package. A CTE mismatch may occur, for example, between the IC dies and the encapsulant material and/or the underfill material. The high magnitudes of stress resulting from CTE mismatch(es) in the multi-die package may cause warpage, bending, and/or cracking in the multi-die package when the multi-die package is under a thermal load. The warpage, bending, and/or cracking in the multi-die package may result in physical damage to the multi-die package (e.g., delamination of the underfill material from the IC dies, cracking of the underfill material), which may result in failure of the multi-die package and/or failure of one or more IC dies included therein.

Some implementations described herein provide a multi-die package that includes non-active dies among the IC dies included in the multi-die package. The non-active dies may be included to reduce the amount of encapsulant material and/or an underfill material that is used in the multi-die package, which reduces the amount of CTE mismatch in the multi-die package. Moreover, a plurality of non-active dies may be positioned in an adjacent manner between two or more active IC dies (e.g., between a logic IC die and a high bandwidth memory (HBM) IC die, between two HBM IC dies). The use of a plurality of non-active dies in a particular area of the multi-die package increases the quantity of gaps in the multi-die package as opposed to the use of a single non-active die in the particular area. The increased quantity of gaps in the multi-die package provides an increased amount of area in the multi-die package for stress and strain absorption, and enables more even distribution of stresses and strains in the multi-die package relative to the use of a single non-active die in the particular area. Accordingly, the use of a plurality of non-active dies in a particular area of the multi-die package may reduce the amount of CTE mismatching in the multi-die package, which may reduce the likelihood of warpage, bending, and/or cracking in the multi-die package. The reduced likelihood of warpage, bending, and/or cracking in the multi-die package may reduce the likelihood of failure of the multi-die package and/or may reduce the likelihood of failure of one or more IC dies included therein, which may increase multi-die package yield.

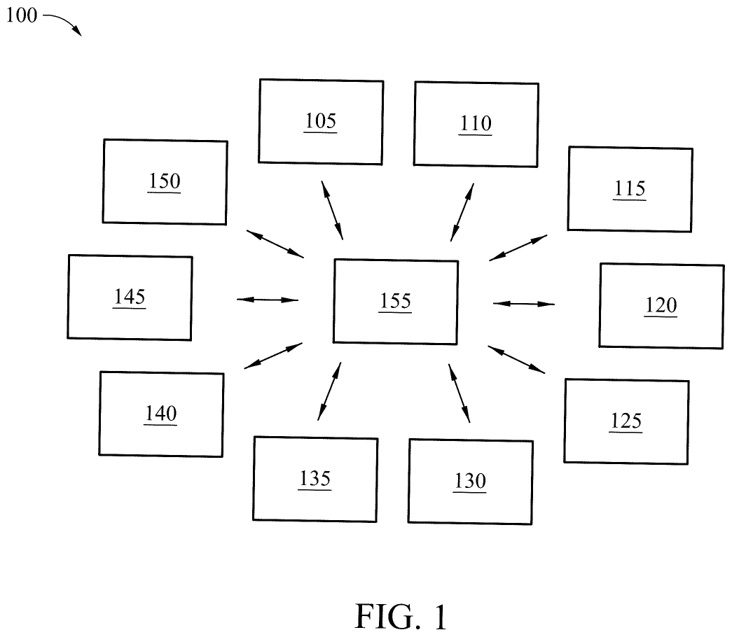

FIG. 1 is a diagram of an example environment 100 in which systems and/or methods described herein may be implemented. As shown in FIG. 1, environment 100 may include a plurality of semiconductor processing tool sets 105-150 and a transport tool set 155. The plurality of semiconductor processing tool sets 105-150 may include a redistribution layer (RDL) tool set 105, a planarization tool set 110, an connection tool set 115, an automated test equipment (ATE) tool set 120, a singulation tool set 125, a die-attach tool set 130, an encapsulation tool set 135, a printed circuit board (PCB) tool set 140, a surface mount (SMT) tool set 145, and a finished goods tool set 150. The semiconductor processing tool sets 105-150 of example environment 100 may be included in one or more facilities, such as a semiconductor clean or semi-clean room, a semiconductor foundry, a semiconductor processing facility, an outsourced assembly and test (OSAT) facility, and/or a manufacturing facility, among other examples.

In some implementations, the semiconductor processing tool sets 105-150, and operations performed by the semiconductor processing tool sets 105-150, are distributed across multiple facilities. Additionally, or alternatively, one or more of the semiconductor processing tool sets 105-150 may be subdivided across the multiple facilities. Sequences of operations performed by the semiconductor processing tool sets 105-150 may vary based on a type of the semiconductor package or a state of completion of the semiconductor package.

One or more of the semiconductor processing tool sets 105-150 may perform a combination of operations to assemble a semiconductor package (e.g., attach one or more IC dies to a substrate, where the substrate provides an external connectivity to a computing device, among other examples). Additionally, or alternatively, one or more of the semiconductor processing tool sets 105-150 may perform a combination of operations to ensure a quality and/or a reliability of the semiconductor package (e.g., test and sort the one or more IC dies, and/or the semiconductor package, at various stages of manufacturing).

The semiconductor package may correspond to a type of semiconductor package. For example, the semiconductor package may correspond to a flipchip (FC) type of semiconductor package, a ball grid array (BGA) type of semiconductor package, a multi-chip package (MCP) type of semiconductor package, or a chip scale package (CSP) type of semiconductor package. Additionally, or alternatively, the semiconductor package may correspond to a plastic leadless chip carrier (PLCC) type of semiconductor package, a system-in-package (SIP) type of semiconductor package, a ceramic leadless chip carrier (CLCC) type of semiconductor package, or a thin small outline package (TSOP) type of semiconductor package, among other examples.

The RDL tool set 105 includes one or more tools capable of forming one or more layers and patterns of materials (e.g., dielectric layers, conductive redistribution layers, and/or vertical connection access structures (vias), among other examples) on a semiconductor substrate (e.g., a semiconductor wafer, among other examples). The RDL tool set 105 may include a combination of one or more photolithography tools (e.g., a photolithography exposure tool, a photoresist dispense tool, a photoresist develop tool, among other examples), a combination of one or more etch tools (e.g., a plasma-based etched tool, a dry-etch tool, or a wet-etch tool, among other examples), and one or more deposition tools (e.g., a chemical vapor deposition (CVD) tool, a physical vapor deposition (PVD) tool, an atomic layer deposition (ALD) tool, or a plating tool, among other examples). In some implementations, the example environment 100 includes a plurality of types of such tools as part of RDL tool set 105.

The planarization tool set 110 includes one or more tools that are capable of polishing or planarizing various layers of the semiconductor substrate (e.g., the semiconductor wafer). The planarization tool set 110 may also include tools capable of thinning the semiconductor substrate. The planarization tool set 110 may include a chemical mechanical planarization (CMP) tool or a lapping tool, among other examples. In some implementations, the example environment 100 includes a plurality of types of such tools as part of the planarization tool set 110.

The connection tool set 115 includes one or more tools that are capable of forming connection structures (e.g., electrically-conductive structures) as part of the semiconductor package. The connection structures formed by the connection tool set 115 may include a wire, a stud, a pillar, a bump, or a solderball, among other examples. The connection structures formed by the connection tool set 115 may include materials such as a gold (Au) material, a copper (Cu) material, a silver (Ag) material, a nickel (Ni) material, a tin (Sn) material, or a palladium (Pd) material, among other examples. The connection tool set 115 may include a bumping tool, a wirebond tool, or a plating tool, among other examples. In some implementations, the example environment 100 includes a plurality of types of such tools as part of the connection tool set 115.

The ATE tool set 120 includes one or more tools that are capable of testing a quality and a reliability of the one or more IC dies and/or the semiconductor package (e.g., the one or more IC dies after encapsulation). The ATE tool set 120 may perform wafer testing operations, known good die (KGD) testing operations, semiconductor package testing operations, or system-level (e.g., a circuit board populated with one or more semiconductor packages and/or one or more IC dies) testing operations, among other examples. The ATE tool set 120 may include a parametric tester tool, a speed tester tool, and/or a burn-in tool, among other examples. Additionally, or alternatively, the ATE tool set 120 may include a prober tool, probe card tooling, test interface tooling, test socket tooling, a test handler tool, burn-in board tooling, and/or a burn-in board loader/unloader tool, among other examples. In some implementations, the example environment 100 includes a plurality of types of such tools as part of the ATE tool set 120.

The singulation tool set 125 includes one or more tools that are capable of singulating (e.g., separating, removing) the one or more IC dies or the semiconductor package from a carrier. For example, the singulation tool set 125 may include a dicing tool, a sawing tool, or a laser tool that cuts the one or more IC dies from the semiconductor substrate. Additionally, or alternatively, the singulation tool set 125 may include a trim-and-form tool that excises the semiconductor package from a leadframe. Additionally, or alternatively, the singulation tool set 125 may include a router tool or a laser tool that removes the semiconductor package from a strip or a panel of an organic substrate material, among other examples. In some implementations, the example environment 100 includes a plurality of types of such tools as part of the singulation tool set 125.

The die-attach tool set 130 includes one or more tools that are capable of attaching the one or more IC dies to the interposer, the leadframe, and/or the strip of the organic substrate material, among other examples. The die-attach tool set 130 may include a pick-and-place tool, a taping tool, a reflow tool (e.g., a furnace), a soldering tool, or an epoxy dispense tool, among other examples. In some implementations, the example environment 100 includes a plurality of types of such tools as part of the die-attach tool set 130.

The encapsulation tool set 135 includes one or more tools that are capable of encapsulating the one or more IC dies (e.g., the one or more IC dies attached to the interposer, the leadframe, or the strip of organic substrate material). For example, the encapsulation tool set 135 may include a molding tool that encapsulates the one or more IC dies in a plastic molding compound. Additionally, or alternatively, the encapsulation tool set 135 may include a dispense tool that dispenses an epoxy polymer underfill material between the one or more IC dies and an underlying surface (e.g., the interposer or the strip of organic substrate material, among other examples). In some implementations, the example environment 100 includes a plurality of types of such tools as part of the encapsulation tool set 135.

The PCB tool set 140 incudes one or more tools that are capable of forming a PCB having one or more layers of electrically-conductive traces. The PCB tool set 140 may form a type of PCB, such as a single layer PCB, a multi-layer PCB, or a high density connection (HDI) PCB, among other examples. In some implementations, the PCB tool set 140 forms the interposer and/or the substrate using one or more layers of a buildup film material and/or fiberglass reinforced epoxy material. The PCB tool set 140 may include a laminating tool, a plating tool, a photoengraving tool, a laser cutting tool, a pick-and-place tool, an etching tool, a dispense tool, a bonding tool, and/or a curing tool (e.g., a furnace) among other examples. In some implementations, the example environment 100 includes a plurality of types of such tools as part of the PCB tool set 140.

The SMT tool set 145 includes one or more tools that are capable of mounting the semiconductor package to a circuit board (e.g., a central processing unit (CPU) PCB, a memory module PCB, an automotive circuit board, and/or a display system board, among other examples). The SMT tool set 145 may include a stencil tool, a solder paste printing tool, a pick-and-place tool, a reflow tool (e.g., a furnace), and/or an inspection tool, among other examples. In some implementations, the example environment 100 includes a plurality of types of such tools as part of the SMT tool set 145.

The finished goods tool set 150 includes one or more tools that are capable of preparing a final product including the semiconductor package for shipment to a customer. The finished goods tool set 150 may include a tape-and-reel tool, a pick-and-place tool, a carrier tray stacking tool, a boxing tool, a drop-testing tool, a carousel tool, a controlled-environment storage tool, and/or a sealing tool, among other examples. In some implementations, the example environment 100 includes a plurality of types of such tools as part of the finished goods tool set 150.

The transport tool set 155 includes one or more tools that are capable of transporting work-in-process (WIP) between the semiconductor processing tools 105-150. The transport tool set 155 may be configured to accommodate one or more transport carriers such a wafer transport carrier (e.g., a wafer cassette or a front opening unified pod (FOUP), among other examples), a die carrier transport carrier (e.g., a film frame, among other examples), and/or a package transport carrier (e.g., a joint electron device engineering (JEDEC) tray or a carrier tape reel, among other examples). The transport tool set 155 may also be configured to transfer and/or combine WIP amongst transport carriers. The transport tool set 155 may include a pick-and-place tool, a conveyor tool, a robot arm tool, an overhead hoist transport (OHT) tool, an automated materially handling system (AMHS) tool, and/or another type of tool. In some implementations, the example environment 100 includes a plurality of types of such tools as part of the transport tool set 155.

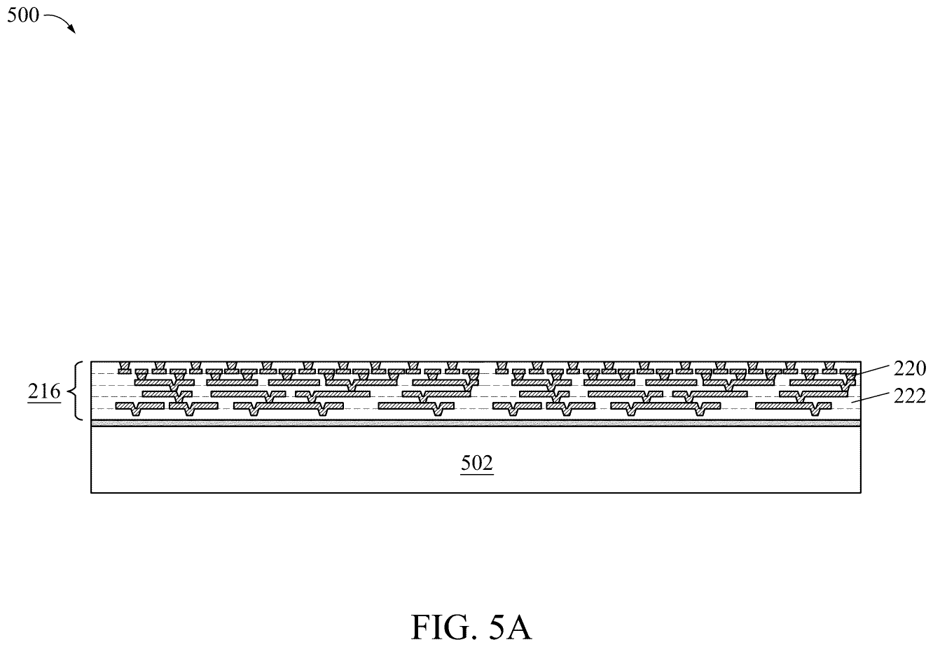

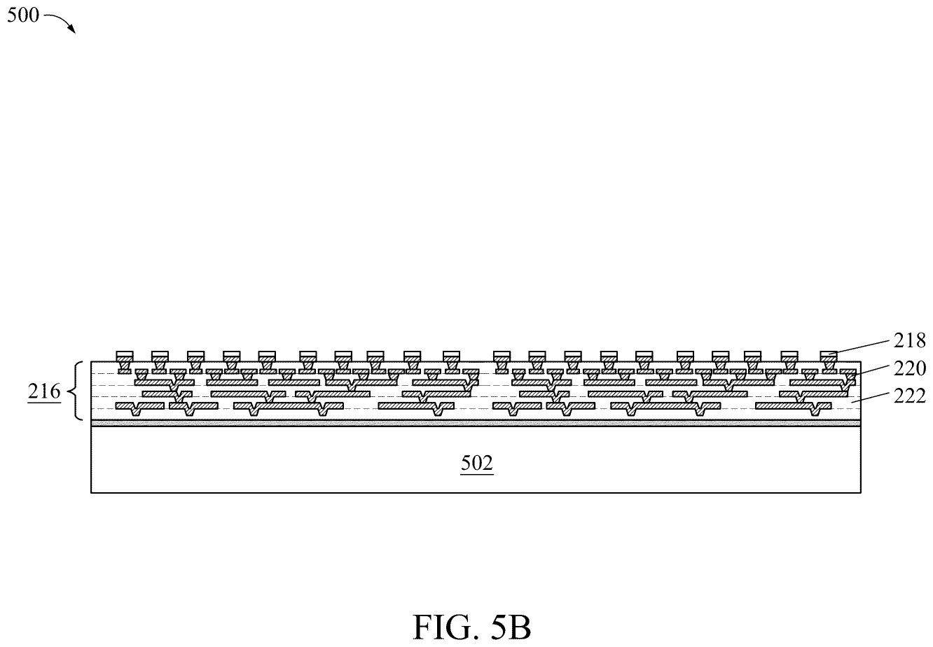

One or more of the semiconductor processing tool sets 105-150 may perform one or more operations described herein. For example, one or more of the semiconductor processing tool sets 105-150 may perform one or more operations described in connection with FIGS. 5A, 5B, 6A-6E, 7A, 7B, 8A-8C, 9A-9C, 10A, and/or 10B, among other examples. As another example, one or more of the semiconductor processing tool sets 105-150 may form an interposer of a multi-die package, may attach a plurality of non-active dies to the interposer, may attaching a plurality of active IC dies to the interposer, where the plurality of non-active dies are arranged side by side in a row on the interposer such that the plurality of non-active dies and the plurality of active IC dies are spaced apart by gaps, may fill the gaps with at least one of an underfill material or a molding compound, and/or may attach the multi-die package to a device package substrate after filling the gaps with the at least one of the underfill material or the molding compound, among other examples.

The number and arrangement of tool sets shown in FIG. 1 are provided as one or more examples. In practice, there may be additional tool sets, different tool sets, or differently arranged tool sets than those shown in FIG. 1. Furthermore, two or more tool sets shown in FIG. 1 may be implemented within a single tool set, or a tool set shown in FIG. 1 may be implemented as multiple, distributed tool sets. Additionally, or alternatively, one or more tool sets of environment 100 may perform one or more functions described as being performed by another tool set of environment 100.

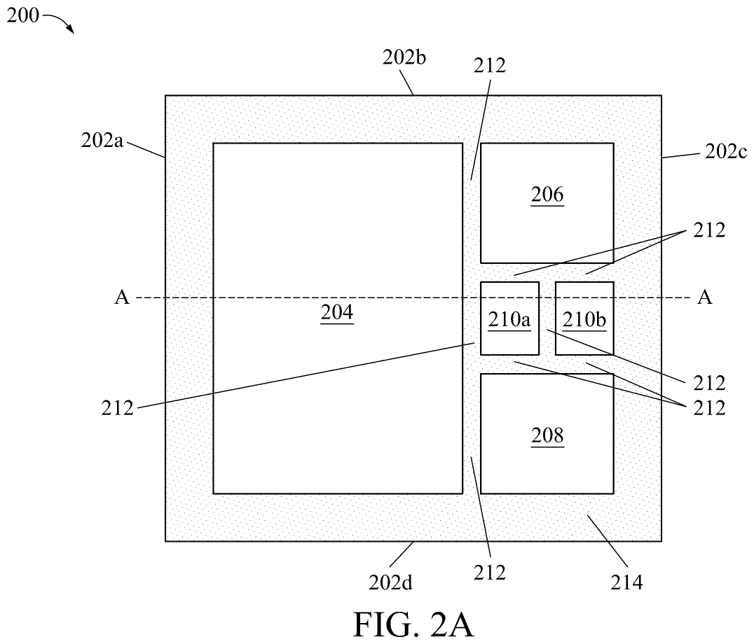

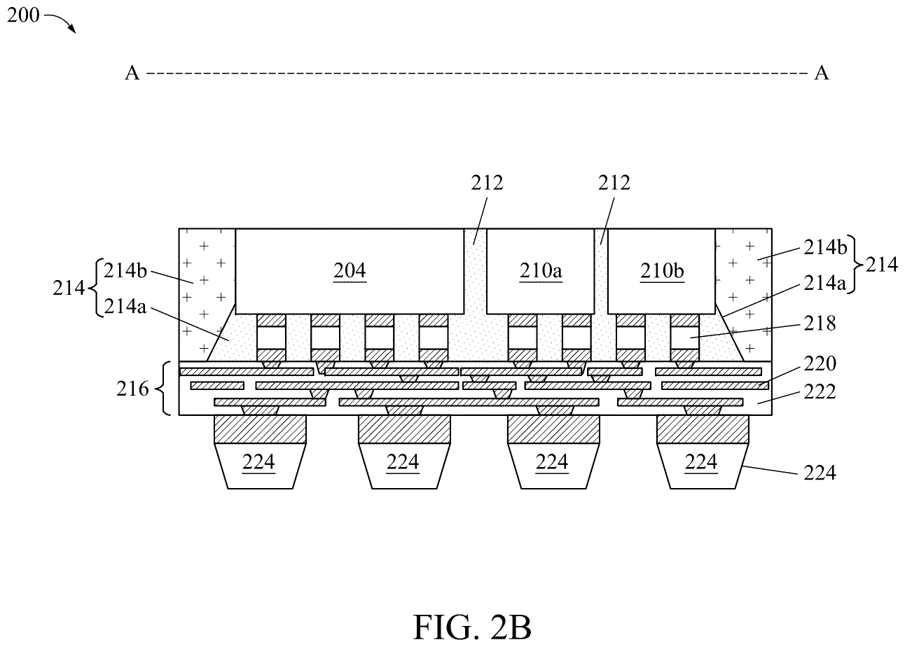

FIGS. 2A and 2B are diagrams of an example multi-die package 200 described herein. The multi-die package 200 includes a packaged semiconductor device that includes a plurality of dies or chips. The plurality of dies may be vertically arranged and/or stacked, horizontally arranged, and/or a combination thereof. The multi-die package 200 may be referred to as a chip on wafer (CoW) package, a three dimensional (3D) package, a 2.5D package, and/or another type of semiconductor package that includes a plurality of dies or chips.

FIG. 2A illustrates a top view of the multi-die package 200. As shown in FIG. 2A, the multi-die package 200 may include a plurality of outer edges that correspond to the perimeter of the multi-die package 200. The plurality of outer edges may include an outer edge 202a, an outer edge 202b, an outer edge 202c, and an outer edge 202d, among other examples. As shown in the example in FIG. 2A, the multi-die package 200 may be approximately square shaped or approximately rectangular shaped. Accordingly, the outer edges 202a and 202c may be located on opposing sides of the multi-die package 200, the outer edges 202b and 202d may be located on opposing sides of the multi-die package 200, the outer edge 202a and 202b may be approximately orthogonal, the outer edge 202a and 202d may be approximately orthogonal, the outer edge 202c and 202b may be approximately orthogonal, and the outer edge 202c and 202d may be approximately orthogonal. However, in other implementations, the multi-die package 200 may be approximately circle shaped (or generally round shaped), hexagon shaped, or another shape. Alternatively, the multi-die package 200 may include a non-standard shape or an amorphous shape.

As further shown in FIG. 2A, the multi-die package 200 may include a plurality of active IC dies, such as active IC dies 204-208 for example. The active IC dies 204-208 may include dies that include the active integrated circuits of the multi-die package 200 and perform the electrical and processing functions of the multi-die package 200. Examples of active IC dies 204-208 include a logic IC die, a memory IC die, an HBM IC die, an I/O die, a system-on-chip (SoC) IC die, a dynamic random access memory (DRAM) IC die, a static random access memory (SRAM) IC die, a central processing unit (CPU) IC die, a graphics processing unit (GPU) IC die, a digital signal processing (DSP) IC die, an application specific integrated circuit (ASIC) IC die, and/or another type of active IC die. The active IC dies 204-208 may be various sizes and/or shapes, and may be positioned in various locations and arrangements on the multi-die package 200.

The multi-die package 200 may further include non-active dies 210a and 210b. In some implementations, the multi-die package 200 includes a greater quantity of non-active dies than the quantity shown in the example in FIG. 2A. The non-active dies 210a and 210b may include dies that are passive components and/or dies that do not perform electrical and/or processing functions of the multi-die package 200. Examples of non-active dies 210a and 210b include dummy dies, integrated passive device (IPD) dies, and/or other types of non-active dies. A dummy die may also be referred to as an insertion die, a filler die, and/or another type of die that does not perform electrical and/or processing functions of the multi-die package 200. An IPD die may include a capacitor or capacitor die, a resistor or resistor die, an inductor or inductor die, or a combination thereof.

The quantity and/or position of the non-active dies 210a and 210b in the top view of the multi-die package 200 (e.g., the horizontal arrangement of dies in the top view) may be determined and/or selected to achieve and/or satisfy one or more parameters for the multi-die package 200. Unused area (e.g., area that is not occupied by at least one die) in the horizontal arrangement of dies in the multi-die package 200 may result in reduced stiffness and/or reduced rigidity for the multi-die package 200. This may increase the likelihood of bending, warpage, and/or physical damage to the multi-die package 200. Accordingly, the quantity and/or position of the non-active dies 210a and 210b may be determined and/or selected to reduce and/or minimize unused area in the horizontal arrangement of dies in the top view. Thus, the non-active dies 210a and 210b may be positioned in unused area between two or more active IC dies (e.g., between active IC dies 206 and 208), may be positioned in unused area adjacent to (or next to) one or more active IC dies (e.g., next to the active IC die 204), or a combination thereof to minimize unused area in the horizontal arrangement of dies in the top view.

The non-active dies 210a and 210b may be positioned side by side or next to each other (e.g., as opposed to being separated by one or more of the active IC dies 204-208). In other words, the non-active die 210a may be positioned side-by-side with and/or next to the non-active die 210b, and the non-active die 210b may be positioned side-by-side with and/or next to the non-active die 210a.

The non-active die 210a may be positioned closer to the active IC die 204 (and the center of the multi-die package 200) relative to the non-active die 210b, whereas the non-active die 210b may be positioned closer to the outer edge 202c of the multi-die package 200 relative to the non-active die 210a. Accordingly, the non-active dies 210a and 210b may be positioned in a row along a direction between the outer edge 202a and the outer edge 202c, as shown in the example in FIG. 2A. However, in other implementations, the non-active dies 210a and 210b may be positioned in a row along a direction between the outer edge 202b and the outer edge 202d.

As further shown in FIG. 2A, the active IC dies 204-208 and the non-active dies 210a and 210b may be spaced apart and/or separated by gaps 212 in the multi-die package 200. For example, the active IC die 204 and the active IC die 206 may be spaced apart and/or separated by a gap 212. As another example, the active IC die 204 and the active IC die 208 may be spaced apart and/or separated by a gap 212. As another example, the active IC die 204 and the non-active die 210a may be spaced apart and/or separated by a gap 212. As another example, the active IC die 206 and the non-active die 210a may be spaced apart and/or separated by a gap 212. As another example, the active IC die 206 and the non-active die 210b may be spaced apart and/or separated by a gap 212. As another example, the active IC die 208 and the non-active die 210a may be spaced apart and/or separated by a gap 212. As another example, the active IC die 208 and the non-active die 210b may be spaced apart and/or separated by a gap 212. As another example, the non-active die 210a and the non-active die 210b may be spaced apart and/or separated by a gap 212.

The gaps 212 may provide physical and/or electrical separation between the active IC dies 204-208 and the non-active dies 210a and 210b. The gaps 212 may be filled with a filler material 214, which may provide additional electrical isolation and/or may provide added rigidity and/or structural integrity for the active IC dies 204-208 and the non-active dies 210a and 210b. The filler material 214 may include one or more types of non-conductive materials and/or insulating materials. The filler material 214 may fill in the gaps 212 between two or more of the active IC dies 204-208, may fill in the gaps 212 between two or more of the non-active dies 210a and 210b, and/or may fill in the gaps 212 between one or more of the active IC dies 204-208 and one or more of the non-active dies 210a and 210b, among other examples. The filler material 214 may fill in other areas around the active IC dies 204-208 and the non-active dies 210a and 210b that are not occupied by dies in the multi-die package 200.

Including two or more non-active dies in the area occupied by the non-active dies 210a and 210b, as opposed to a single non-active die, increases the quantity of gaps 212 in the area between the active IC dies 204-208 while still providing sufficient horizontal coverage of the multi-die package 200 by dies in the multi-die package 200. The sufficient horizontal coverage of the multi-die package 200 by dies in the multi-die package 200 provides sufficient stiffness in the multi-die package 200 while the increased quantity of gaps 212 provides increased distribution of stresses and strains in the multi-die package 200. In particular, the magnitude of stresses and strains experienced by a particular gap 212 in the multi-die package 200 may be reduced such that the magnitudes of stresses and strains in the multi-die package 200 is more evenly distributed to other gaps 212 in the multi-die package 200. As an example, including non-active dies 210a and 210b provides an additional gap in the multi-die package 200 between the non-active die 210a and the non-active die 210b. This additional gap 212 between the non-active die 210a and the non-active die 210b provides additional area in the multi-die package 200 for stress and strain absorption, which may reduce the magnitude of stresses and strains that may be experienced in the gap 212 between the non-active die 210a and the active IC die 204 than if a single non-active die (an no additional gap 212) were included in place of the non-active dies 210a and 210b.

FIG. 2B illustrates a cross-section view of the multi-die package 200 along the line A-A in FIG. 2A (e.g., along a direction between the outer edge 202a and the outer edge 202c). As shown in FIG. 2B, the active IC die 204 and the non-active dies 210a and 210b are attached to, mounted to, and/or bonded to an interposer 216 of the multi-die package 200. The active IC dies 206 and 208 may be attached to, mounted to, and/or bonded to the interposer 216 in a similar manner.

The active IC dies 204-208 and the non-active dies 210a and 210b may be attached to the interposer 216 by a plurality of connection structures 218. The connection structures 218 may include a stud, a pillar, a bump, a solderball, a micro-bump, an under-bump metallization (UBM) structure, and/or another type of connection structure, among other examples. The connection structures 218 may include one or more materials, such as a gold (Au) material, a copper (Cu) material, a silver (Ag) material, a nickel (Ni) material, a tin (Sn) material, a lead (Pb) material, or a palladium (Pd) material, among other examples. In some implementations, the one or more materials may be lead-free (e.g., Pb-free).

The connection structures 218 may connect lands (e.g., pads) on bottom surfaces of the active IC dies 204-208 and the non-active dies 210a and 210b to lands on a top surface of the interposer 216. In some implementations, the connection structures 218 may include one or more electrical connections for signaling (e.g., corresponding lands of the active IC dies 204-208, the non-active dies 210a and 210b, and/or the interposer 216 are electrically connected to respective circuitry and/or traces of the active IC dies 204-208, the non-active dies 210a and 210b, and/or the interposer 216).

In some implementations, the connection structures 218 may include one or more mechanical connections for attachment purposes and/or spacing purposes (e.g., corresponding lands of the active IC dies 204-208, the non-active dies 210a and 210b, and/or the interposer 216 are not electrically connected to respective circuitry and/or traces of the active IC dies 204-208, the non-active dies 210a and 210b, and/or the interposer 216). In some implementations, one or more of the connection structures 218 may function both electrically and mechanically.

As further shown in FIG. 2B, one or more types of filler materials 214 may be included above the interposer 216 and in areas surrounding the active IC dies 204-208, the non-active dies 210a and 210b, and/or the connection structures 218. For example, an underfill material 214a may be included between the connection structures 218 under the active IC dies 204-208, and between the connection structures 218 under the non-active dies 210a and 210b. As another example, an encapsulant material (also referred to as a molding compound) 214b may be included over and/or on the interposer 216 and/or over and/or on portions of the underfill material 214a around the perimeter of the multi-die package 200.

The underfill material 214a may include a polymer, one or more fillers dispersed in a resin, an epoxy-based resin, and/or another type of insulating material. In some implementations, the underfill material 214a fills in the gaps 212 between the non-active dies 210a and 210b, between two or more of the active IC dies 204-208, and/or between one or more of the active IC dies 204-208 and one or more of the non-active dies 210a and 210b. In some implementations, the underfill material 214a may fully fill the gaps 212 approximately up to a top surface of the active IC dies 204-208 and/or the non-active dies 210a and 210b. The underfill material 214a may extend outward from one or more of the active IC dies 204-208 and/or one or more of the non-active dies 210a and 210b toward the perimeter of the multi-die package 200. For example, the underfill material 214a may extend outward in a tapered or sloped manner. As another example, underfill material 214a may extend outward in a concave manner or in a convex manner.

The encapsulant material 214b may include a polymer, one or more fillers dispersed in a resin, an epoxy-based resin, and/or another type of insulating material. In some implementations, the encapsulant material 214b may fully surround the top surfaces of the active IC dies 204-208 and the non-active dies 210a and 210b such that the encapsulant material 214b protects the active IC dies 204-208 and the non-active dies 210a and 210b in the multi-die package 200.

The interposer 216 may include a redistribution structure and/or another type of structure that includes a plurality of redistribution layers (RDLs) 220 in one or more layers of dielectric material 222. The interposer 216 may be configured to distribute electrical signals between the connection structures 218 and connection structures 224 on opposing sides of the interposer 216. The RDLs 220 and the connection structures 224 may include one or more materials such as a gold (Au) material, a copper (Cu) material, a silver (Ag) material, a nickel (Ni) material, a tin (Sn) material, or a palladium (Pd) material, among other examples. In some implementations, the RDLs 220 includes one or more conductive vertical access connection structures (vias) that connect one or more metallization layers of the RDLs 220.

As indicated above, FIGS. 2A and 2B are provided as an example. Other examples may differ from what is described with regard to FIGS. 2A and 2B.

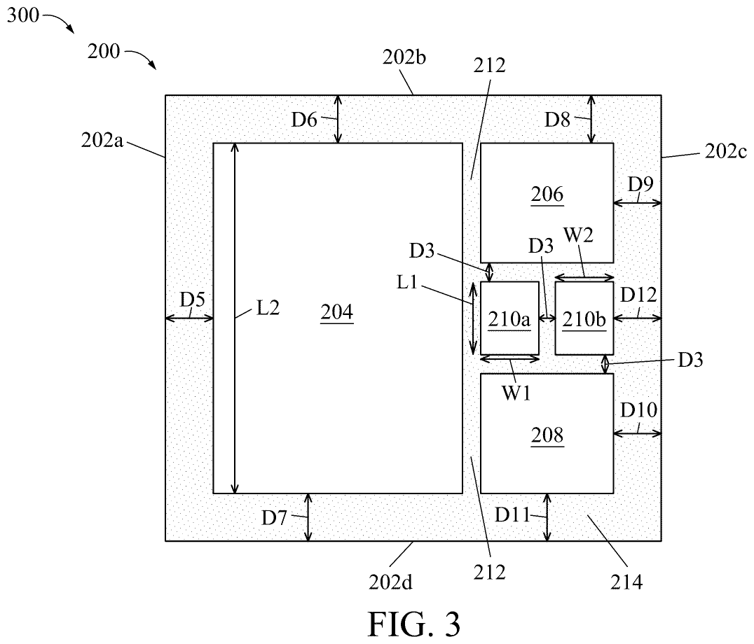

FIG. 3 is a diagram of an example implementation 300 described herein. The example implementation 300 includes an example non-active die configuration for the multi-die package 200 in which the multi-die package 200 includes a plurality of non-active dies 210a and 210b having the same approximate width and the same approximate length.

As shown in FIG. 3, the non-active dies 210a and 210b may each have a length L1. As indicated above, the length L1 may be approximately the same for each of the non-active dies 210a and 210b to reduce the complexity of the horizontal layout of dies in the multi-die package 200 and to reduce the likelihood of uneven distribution of the filler material 214 in the multi-die package 200. In some implementations, the length L1 is included in a range of approximately 1.4 millimeters to approximately 26 millimeters such that the non-active dies 210a and 210b are a sufficient size for the die-attach tool set 130 to pick and place the non-active dies 210a and 210b on the interposer 216 while providing sufficient size for the gaps 212 in the multi-die package 200. However, other values for the range are within the scope of the present disclosure. The length L1 of the non-active dies 210a and 210b may be lesser relative to a length L2 of the active IC die 204.

As further shown in FIG. 3, two or more edges of the non-active dies 210a and 210b may be aligned in the multi-die package 200. For example, respective edges of the non-active dies 210a and 210b next to and/or facing the active IC die 206 may be approximately aligned in that the respective edges may be approximately located along a same horizontal plane between the outer edge 202a and the outer edge 202c. As another example, respective edges of the non-active dies 210a and 210b next to and/or facing the active IC die 208 may be approximately aligned in that the respective edges may be approximately located along a same horizontal plane between the outer edge 202a and the outer edge 202c. The alignment of the non-active dies 210a and 210b, alone or in combination with the length L1 of the non-active dies 210a and 210b being approximately the same, may further reduce the complexity of the horizontal layout of dies in the multi-die package 200 and/or may further reduce the likelihood of uneven distribution of the filler material 214 in the multi-die package 200.

The non-active dies 210a and 210b may have a width W1 and W2, respectively. As indicated above, the widths W1 and W2 may be approximately the same for each of the non-active dies 210a and 210b. In some implementations, each of the widths W1 and W2 may be greater than or approximately equal to 1.4 millimeters to approximately 26 millimeters such that the non-active dies 210a and 210b are a sufficient size for the die-attach tool set 130 to pick and place the non-active dies 210a and 210b on the interposer 216 while providing sufficient size for the gaps 212 in the multi-die package 200. However, other values for the range are within the scope of the present disclosure. In some implementations, an aspect ratio between the length L1 to the width W1 or with width W2 is included in a range of approximately 1:1 to approximately 5:1 such that the non-active dies 210a and 210b are a sufficient size for the die-attach tool set 130 to pick and place the non-active dies 210a and 210b on the interposer 216 while providing sufficient size for the gaps 212 in the multi-die package 200. However, other values for the range are within the scope of the present disclosure.

As further shown in FIG. 3, the gaps 212 may provide distances D1-D4 between the dies in the multi-die package 200. Accordingly, the width of a gap 212 between the non-active die 210a and the active IC die 204 may correspond to a distance D1 between the non-active die 210a and the active IC die 204. The width of a gap 212 between the non-active die 210a and the non-active die 210b may correspond to a distance D2 between the non-active die 210a and the non-active die 210b. The width of a gap 212 between the non-active die 210a and the active IC die 206 may correspond to a distance D3 between the non-active die 210a and the active IC die 206 (as well as between the non-active die 210b and the active IC die 206). The width of a gap 212 between the non-active die 210b and the active IC die 208 may correspond to a distance D4 between the non-active die 210b and the active IC die 208 (as well as between the non-active die 210a and the active IC die 208). In some implementations, one or more of the distances D1-D4 (and thus, the widths of the gaps 212 between the dies in the multi-die package 200) may be included in a range of approximately 50 microns to approximately 200 microns to provide a sufficiently low likelihood of cracking and die collision in the multi-die package 200 while achieving a sufficiently low magnitude of stress the interposer 216 underneath the dies. However, other values for the range are within the scope of the present disclosure.

As further shown in FIG. 3, the active IC dies 204-208 and the non-active die 210b may be positioned away from the perimeter (e.g., the outer edges 202a-202c) of the multi-die package 200 by distances D5-D12. For example, the active IC die 204 may be positioned away from the outer edge 202a by a distance D5, may be positioned away from the outer edge 202b by a distance D6, and may be positioned away from the outer edge 202d by a distance D7. As another example, the active IC die 206 may be positioned away from the outer edge 202b by a distance D8, and may be positioned away from the outer edge 202c by a distance D9. As another example, the active IC die 208 may be positioned away from the outer edge 202c by a distance D10, and may be positioned away from the outer edge 202d by a distance D11. As another example, the non-active die 210b may be positioned away from the outer edge 202c by a distance D12. In some implementations, one or more of the distances D5-D12 may be included in a range of approximately 60 microns to approximately 150 microns. However, other values for the range are within the scope of the present disclosure. Moreover, two or more of the distances D5-D12 may be different values, two or more of the distances D5-D12 may be the same value, or a combination thereof.

As indicated above, FIG. 3 is provided as an example. Other examples may differ from what is described with regard to FIG. 3.

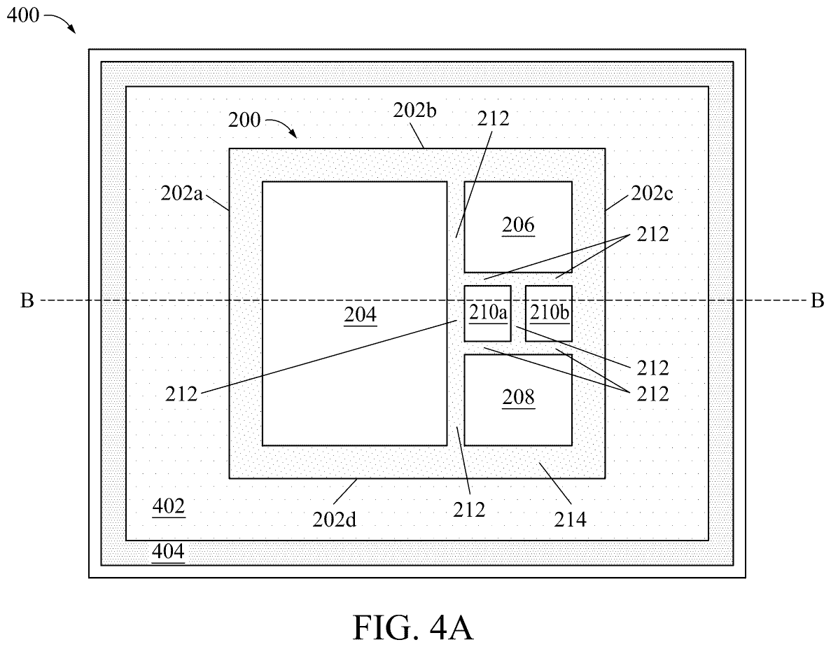

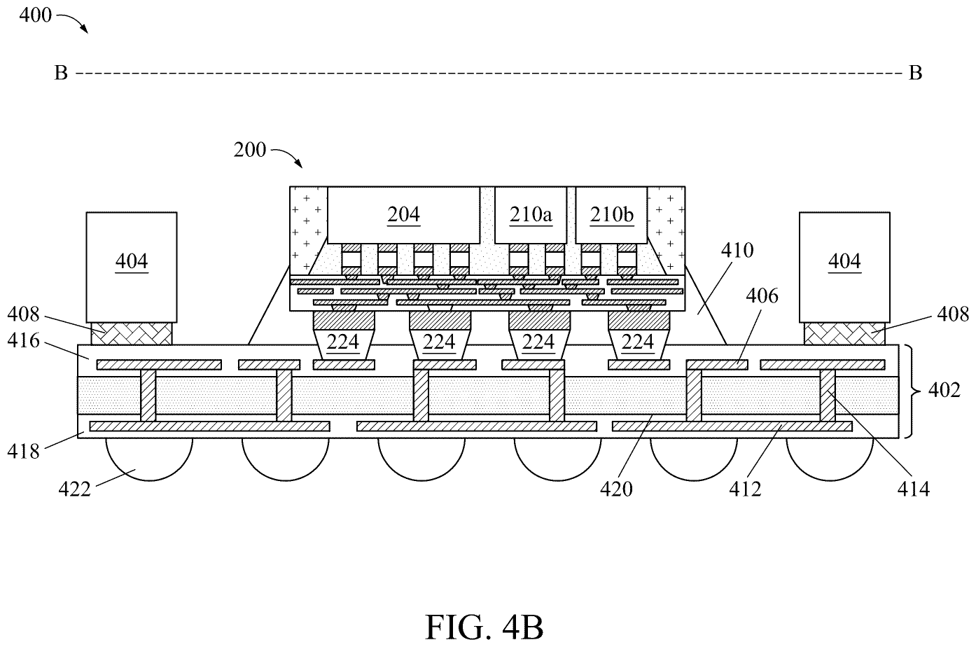

FIGS. 4A and 4B are diagrams of an example device package 400 described herein. The device package 400 includes a packaged semiconductor device that includes one or more multi-die packages 200. In some implementations, a plurality of multi-die packages 200 are vertically arranged and/or stacked, horizontally arranged, and/or a combination thereof in the device package 400. The device package 400 may be referred to as a chip on wafer on substrate (CoWoS) package, a 3D package, a 2.5D package, and/or another type of semiconductor package that includes a one or more multi-die packages 200.

FIG. 4A illustrates a top view of the device package 400. As shown in FIG. 4A, the device package 400 includes the multi-die package 200. The multi-die package 200 includes a plurality of side-by-side non-active dies (e.g., the non-active die 210a and the non-active die 210b) that are positioned between two or more of the active IC dies (e.g., two or more of active IC dies 204-208) of the multi-die package 200.

As further shown in FIG. 4A, the multi-die package 200 is included over and/or on a device package substrate 402. A stiffener structure 404 may be included over and/or on the device package substrate 402 along the outer edges of the device package substrate 402. Accordingly, the device package substrate 402 may be outlined or surrounded by a stiffener structure 404. The multi-die package 200 may be positioned within a perimeter of the stiffener structure 404. The stiffener structure 404 may be included to reduce warpage and bending, and to maintain planarity of the device package substrate 402. The stiffener structure 404 may include active circuitry, a non-active structure, or a combination thereof. The stiffener structure 404 may include one or more metal materials, one or more dielectric materials, and/or one or more materials of another type of material.

FIG. 4B includes a cross-section view along the line B-B in FIG. 4A. As shown in FIG. 4B, multi-die package 200 may be attached to the device package substrate 402. The connection structures 224 of the multi-die package 200 may be connected with an upper layer of conductive structures 406 included in the device package substrate 402. The stiffener structure 404 may be attached to the top surface of the device package substrate 402 by an adhesive layer 408 (e.g., an epoxy, an organic adhesive). Another underfill material 410 may be included under the multi-die package 200 and between the connection structures 224.

As further shown in FIG. 4B, the device package substrate 402 may include a lower layer of conductive structures 412. The upper layer of conductive structures 406 and the lower layer of conductive structures 412 may be electrically connected by vertical connection structures 414, which may include through silicon vias (TSVs), through integrated fanout vias (TIVs), interconnects, and/or another type of conductive structures. The upper layer of conductive structures 406, the lower layer of conductive structures 412, and the vertical connection structures 414 may each include one or more materials such as a gold (Au) material, a copper (Cu) material, a silver (Ag) material, a nickel (Ni) material, a tin (Sn) material, or a palladium (Pd) material, among other examples.

The upper layer of conductive structures 406 may be included in a top layer 416 (e.g., a top core layer) of the device package substrate 402, the lower layer of conductive structures 412 may be included in a bottom layer 418 (e.g., a bottom core layer) of the device package substrate 402, and/or the vertical connection structures 414 may be included in a middle layer 420 (e.g., a middle core layer) of the device package substrate 402. The top layer 416, the bottom layer 418, and the middle layer 420 may each include one or more insulating materials, one or more dielectric materials, and/or one or more other types of non-conductive materials.

The lower layer of conductive structures 412 may be electrically connected with conductive terminals 422. The conductive terminals 422 may include ball grid array (BGA) balls, land grid array (LGA) pads, pin grid array (PGA) pins, and/or another type of conductive terminals.

As indicated above, FIGS. 4A and 4B are provided as an example. Other examples may differ from what is described with regard to FIGS. 4A and 4B.

FIGS. 5A and 5B are diagrams of an example implementation 500 described herein. In particular, the example implementation 500 includes an example process for forming a portion of a multi-die package 200.

As shown in FIG. 5A, an interposer 216 may be formed on a carrier 502. The carrier 502 may include a carrier substrate, a wafer, a dummy wafer, a handle substrate, and/or another type of structure on which a semiconductor wafer may be processed. The RDL tool set 105 may form the interposer 216 may include forming a plurality of layers of the dielectric material 222 and a plurality of the RDLs 220 over and/or on the carrier 502. For example, the RDL tool set 105 may deposit a first layer of the dielectric material 222, may remove portions of the first layer to form recesses in the first layer, and may form a first RDL 220 in the recesses. The RDL tool set 105 may continue to perform similar processing operations to build the interposer 216 until a sufficient or desired arranged of RDLs 220 is achieved.

In some implementations, the layers of the dielectric material 222 are formed of a photo-sensitive material such as polybenzoxazole (PBO), polyimide, benzocyclobutene (BCB), and/or another material. The layers of the dielectric material 222 may be formed by spin coating, lamination, CVD, and/or by performing another suitable deposition. The layers of the dielectric material 222 may then patterned. The patterning may be by an acceptable process, such as by exposing the layers of the dielectric material 222 to a light source (e.g., an ultraviolet (UV) light source, a deep UV (DUV) light source, an extreme UV (EUV) light source) using a lithography mask and developing the pattern in the layers of the dielectric material 222 after exposure.

The RDLs 220 may be formed by forming a seed layer over and/or on the layers of the dielectric material 222 in the recesses. In some implementations, the seed layer includes a metal layer, which may be a single layer or a composite layer including a plurality of sub-layers formed of different materials. In some implementations, the seed layer includes a titanium (Ti) layer and a copper (Cu) layer over the titanium layer. The seed layer may be formed using, for example, PVD (sputtering), electroplating, CVD, and/or another suitable deposition technique.

A photoresist may then be formed and patterned on the seed layer. The photoresist may be formed by spin coating or another suitable deposition technique and may be exposed to light for patterning. The patterning forms openings through the photoresist to expose the seed layer through the photoresist. A conductive material may then be deposited through the openings of the photoresist and onto the exposed portions of the seed layer. The conductive material may be formed by plating, such as electroplating or electroless plating, PVD, CVD, and/or another suitable deposition technique. The combination of the conductive material and underlying portions of the seed layer may correspond to an RDL 220. The photoresist and portions of the seed layer on which the conductive material is not formed may subsequently be removed. The photoresist may be removed by an ashing or stripping process, such as using an oxygen plasma or another suitable chemical. Once the photoresist is removed, exposed portions of the seed layer are removed, such as by using an etching process, such as by wet or dry etching.

As shown in FIG. 5B, connection structures 218 may be formed over and/or on the interposer 216. In particular, the connection tool set 115 may form the connection structures 218 over and/or on the top-most RDL 220 of the interposer 216. In some implementations, the connection structures 218 include via portions extending into the interposer 216, pad portions on and extending along the top surface of the interposer 216, column portions over the pad portions, and/or other portions.

Forming the connection structures 218 may include a plurality of processing operations. A seed layer may be formed over and/or on the top-most RDL 220. In some implementations, the seed layer includes a metal layer, which may be a single layer or a composite layer including a plurality of sub-layers formed of different materials. In some implementations, the seed layer includes a titanium (Ti) layer and a copper (Cu) layer over the titanium layer. The seed layer may be formed using, for example, PVD (sputtering), electroplating, CVD, and/or another suitable deposition technique.

After forming the seed layer, a photoresist may then be formed and patterned on the seed layer. The photoresist may be formed by spin coating or by performing another suitable deposition operation. The photoresist may be exposed to light for patterning. The pattern of the photoresist may correspond to the via portions and the pad portions of the connection structures 218. The patterning may be performed to form openings through the photoresist to expose the seed layer.

A conductive material may then be formed in the openings of the photoresist and on the exposed portions of the seed layer. The conductive material may be formed by plating, such as electroplating or electroless plating, or by performing another suitable deposition operation. In some implementations, the conductive material is formed in a conformal manner such that the conductive material partially fills the openings through the photoresist. The combination of the conductive material and underlying portions of the seed layer may correspond to the via portions and the pad portions of the connection structures 218. The pad portions of the connection structures 218 may be referred to as UBM pads. The via portions of the connection structures 218 may be referred to UBM vias.

The photoresist and portions of the seed layer on which the conductive material is not formed may be subsequently removed. The photoresist may be removed in an ashing operation or a stripping operation. Once the photoresist is removed, exposed portions of the seed layer may be removed by etching process, such as by wet or dry etching.

After forming the via portions and the pad portions, a photoresist is then formed and patterned for forming the column portions of the connection structures 218. A conductive material is then formed in the openings of the photoresist and on the exposed portions of the pad portions to form the column portions of the connection structures 218. The conductive material may be formed in a plating operation, such as electroplating operation or electroless plating operation, and/or in another suitable deposition operation. The column portions of the connection structures 218 may be also referred to as UBM columns.

Subsequently, conductive connectors may be formed over the column portions. In some implementations, where the conductive connectors include a solder material, the solder material may be formed in the openings of the photoresist and on the column portions. Aafter forming the conductive connectors, the photoresist may be removed. The photoresist may be removed in an ashing operation or a stripping operation, among other examples.

As indicated above, FIGS. 5A and 5B are provided as an example. Other examples may differ from what is described with regard to FIGS. 5A and 5B.

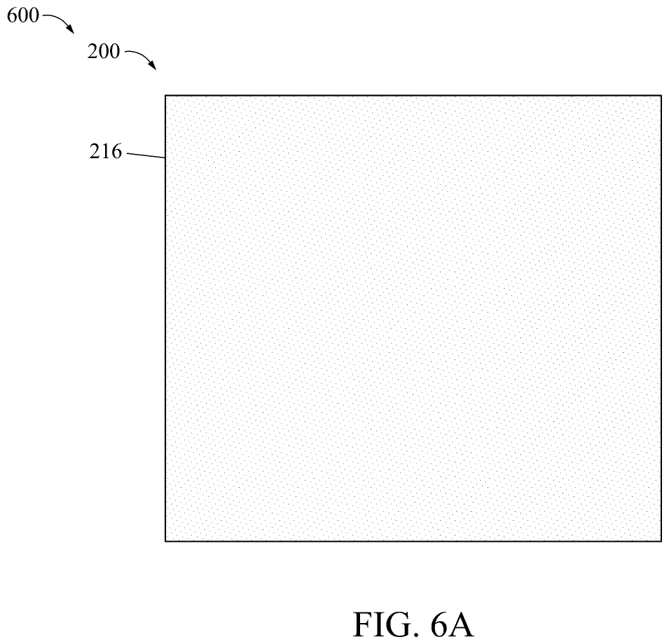

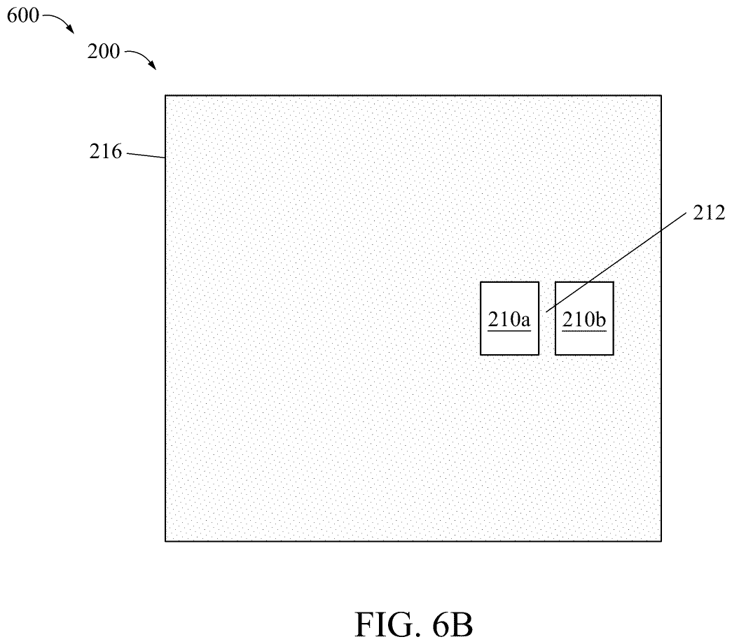

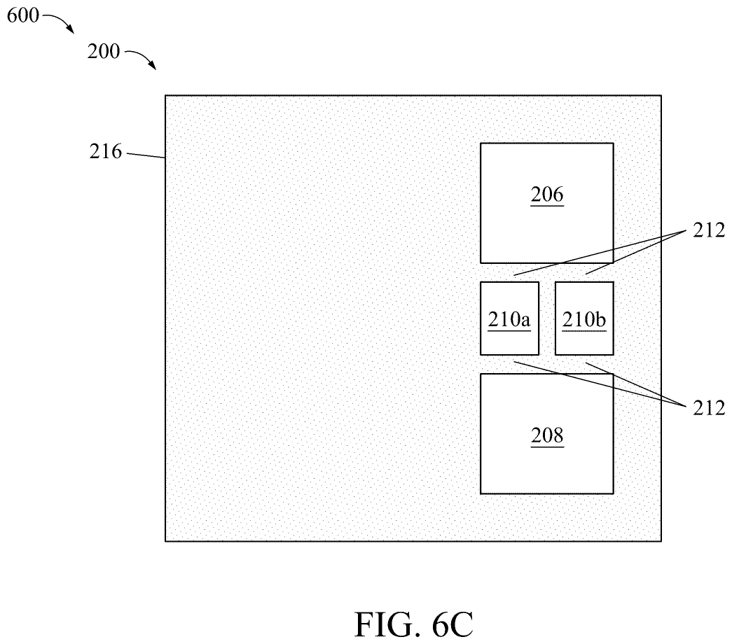

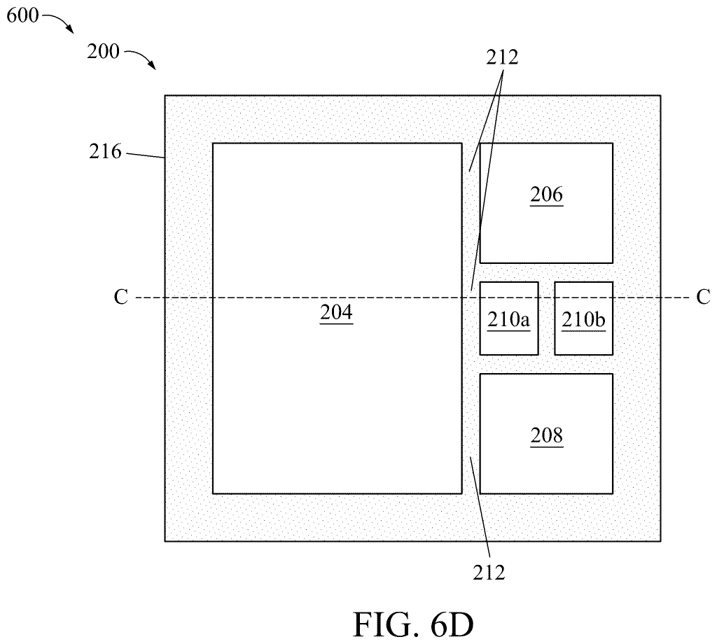

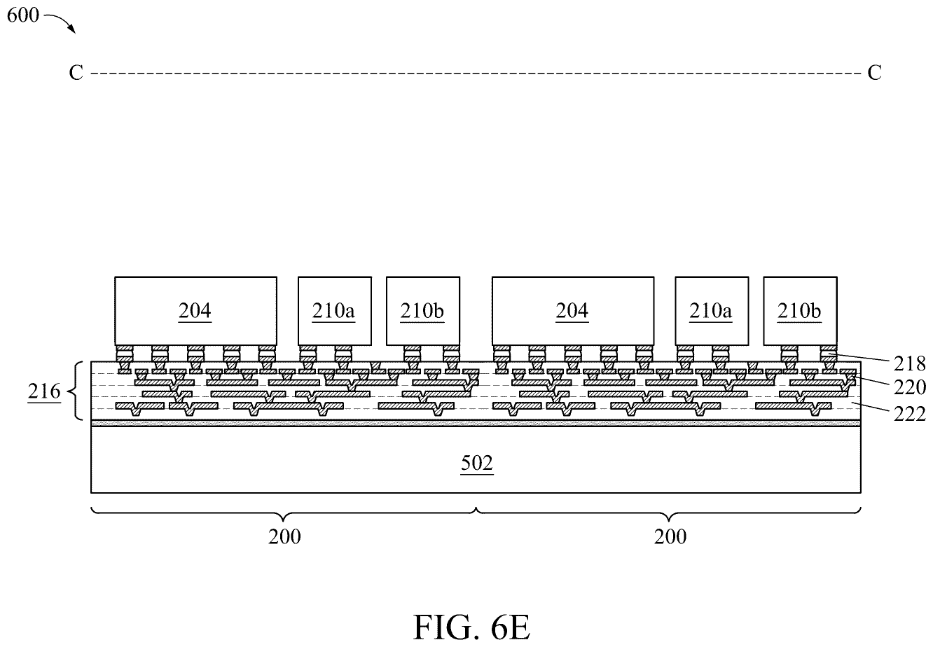

FIGS. 6A-6E are diagrams of an example implementation 600 described herein. The example implementation 600 may include an example of attaching dies to the interposer 216 of a multi-die package 200. In some implementations, one or more of the operations described in connection with FIGS. 6A-6D may be performed after the operations described in connection with the example implementation 500. FIG. 6A illustrates a top view of the interposer 216 after the interposer is formed.

As shown in FIG. 6B, non-active dies 210a and 210b may be attached to the interposer 216. The die-attach tool set 130 may position the non-active dies 210a and 210b over and/or on the interposer 216 such that the non-active die 210a is adjacent to (e.g., side-by-side with and/or next to) the non-active die 210b, and such that the non-active die 210b is adjacent to (e.g., side-by-side with and/or next to) the non-active die 210a. Moreover, the non-active dies 210a and 210b may be positioned over and/or on the interposer 216 such that a gap 212 is included between the non-active dies 210a and 210b. The non-active dies 210a and 210b may also be positioned over and/or on the interposer 216 such that the non-active die 210a is positioned closer to a center of the interposer 216 relative to the non-active die 210b, and such that the non-active die 210b is positioned closer to an outer edge (e.g., corresponding to the outer edge 202c of the multi-die package 200) of the interposer 216 relative to the non-active die 210a.

As shown in FIG. 6C, active IC dies 206 and 208 may be attached to the interposer 216. The die-attach tool set 130 may position the active IC die 206 adjacent to (e.g., side-by-side with and/or next to) respective first sides of the non-active dies 210a and 210b such that gaps 212 are included between the active IC die 206 and the non-active dies 210a and 210b. The die-attach tool set 130 may position the active IC die 208 adjacent to (e.g., side-by-side with and/or next to) respective second sides of the non-active dies 210a and 210b, opposing the respective first sides, such that gaps 212 are included between the active IC die 208 and the non-active dies 210a and 210b.

As shown in FIG. 6D, an active IC die 204 may be attached to the interposer 216. The die-attach tool set 130 may position the active IC die 204 adjacent to (e.g., side-by-side with and/or next to) a third side of the non-active die 210a such that a gap 212 is included between the active IC die 204 and the non-active die 210a. The third side may be approximately orthogonal to the first side of the non-active die 210a and the second side of the non-active die 210b. The die-attach tool set 130 may position the active IC die 204 adjacent to (e.g., side-by-side with and/or next to) the active IC dies 206 and 208.

FIGS. 6A-6D illustrate an example in which the non-active dies 210a and 210b are attached to the interposer 216 prior to the active IC dies 204-208 being attached to the interposer 216. The active IC dies 204-208 may be more complex and costly relative to the non-active dies 210a and 210b, and the active IC die 204 may be more complex and costly relative to the active IC dies 206 and 208. Accordingly, the non-active dies 210a and 210b and the active IC dies 204-208 may be attached to the interposer 216 in this particular order to reduce the likelihood of and/or to reduce the quantity of active IC dies 204-208 that are scrapped due to damage and/or other processing defects that might occur during attachment of the non-active dies 210a and 210b and the active IC dies 204-208 to the interposer 216. This may reduce the quantity of more complex and costly dies that are scrapped in the process of forming multi-die packages 200. However, other attachment orders for the non-active dies 210a and 210b and the active IC dies 204-208 are within the scope of the present disclosure.

FIG. 6E illustrates a cross-section view of the multi-die package 200 along the line C-C in FIG. 6D. As shown in FIG. 6E, a plurality of multi-die packages 200 may be formed on the same interposer 216. These multi-die packages 200 may be subsequently diced or cut into individual multi-die packages 200 after one or more subsequent processing operations. As further shown in FIG. 6E, each of the multi-die packages 200 may include dies (e.g., active IC dies 204-208 and non-active dies 210a and 210b) that are attached to the interposer 216 by the connection structures 218.

As indicated above, FIGS. 6A-6E are provided as an example. Other examples may differ from what is described with regard to FIGS. 6A-6E.

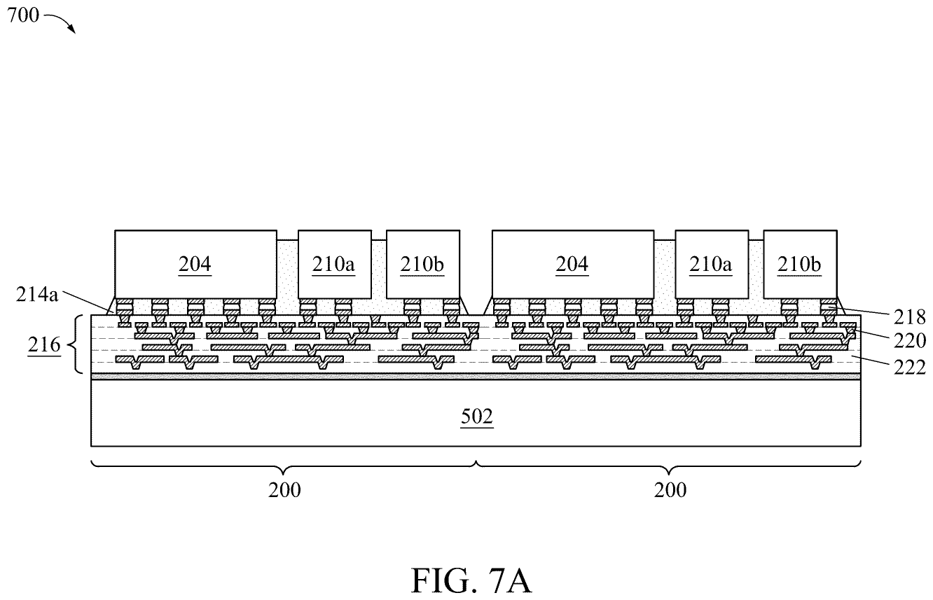

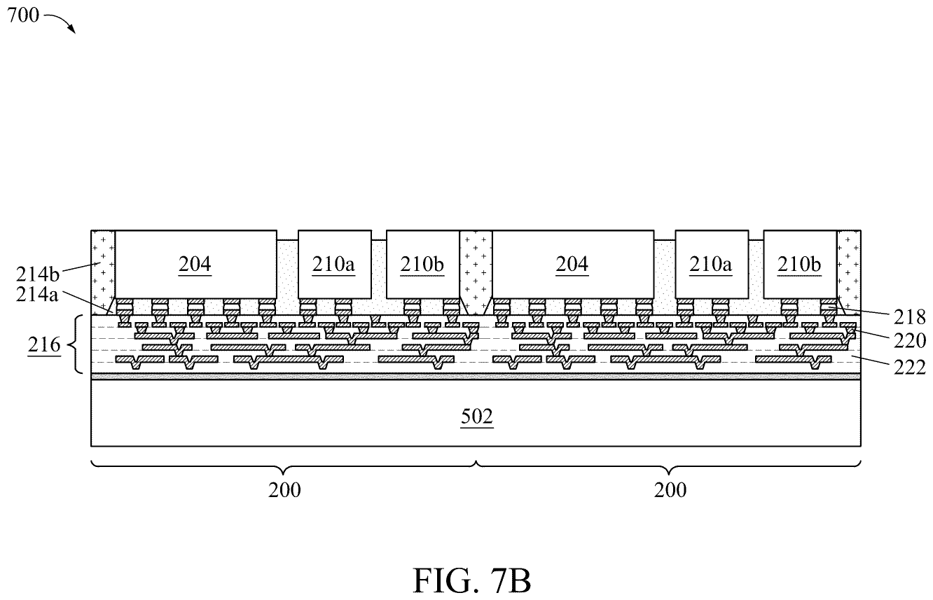

FIGS. 7A and 7B are diagrams of an example implementation 700 described herein. The example implementation 700 may include an example of forming the filler material 214 around the dies of multi-die packages 200. In some implementations, one or more of the operations described in connection with FIGS. 7A and 7B may be performed after the operations described in connection with the example implementation 500 and/or the example implementation 600.

As shown in FIG. 7A, an underfill material 214a may be deposited around the connection structures 218 above the interposer 216. Moreover, the underfill material 214a may be deposited in between and around the sides of the dies on each of the multi-die packages 200. The encapsulation tool set 135 may deposit the underfill material 214a in a capillary flow process, in which the capillary effect is used to deposit the underfill material 214a in between the connection structures 218 and in between the active IC dies 204-208 and the non-active dies 210a and 210b. Alternatively, another suitable technique may be used to deposit the underfill material 214a.

As shown in FIG. 7B, an encapsulant material 214b may be deposed around the perimeters of the multi-die packages 200 and over the underfill material 214a. The encapsulation tool set 135 may deposit the encapsulant material 214b by compression molding, transfer molding, or by another suitable technique. The encapsulant material 214b may be applied in liquid or semi-liquid form and then subsequently cured. In some implementations, the planarization tool set 110 may perform a planarization operation to remove and planarize an upper surface of the encapsulant material 214b. The planarization operation may include a CMP operation, a grinding operation, an etching operation, and/or another suitable process.

As indicated above, FIGS. 7A and 7B are provided as an example. Other examples may differ from what is described with regard to FIGS. 7A and 7B.

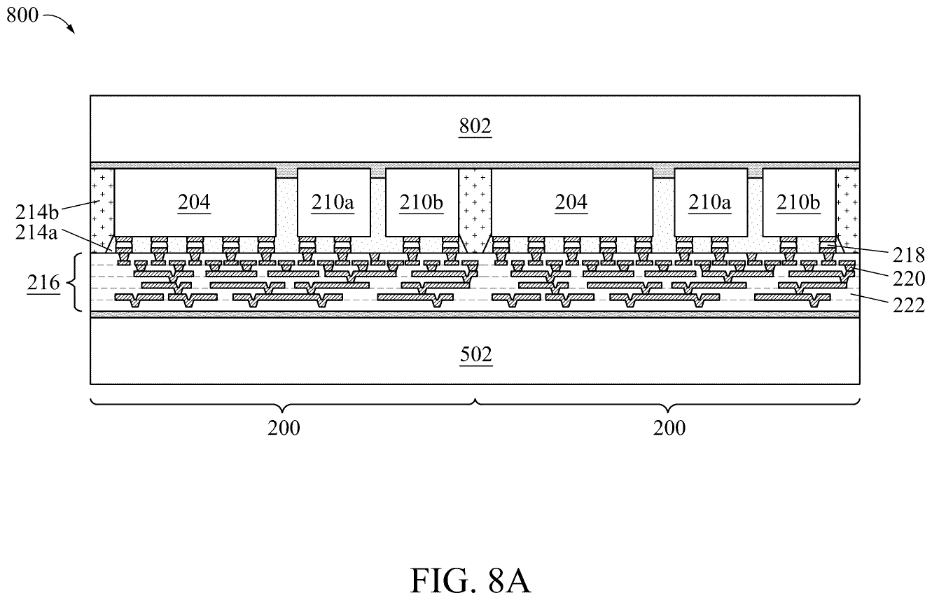

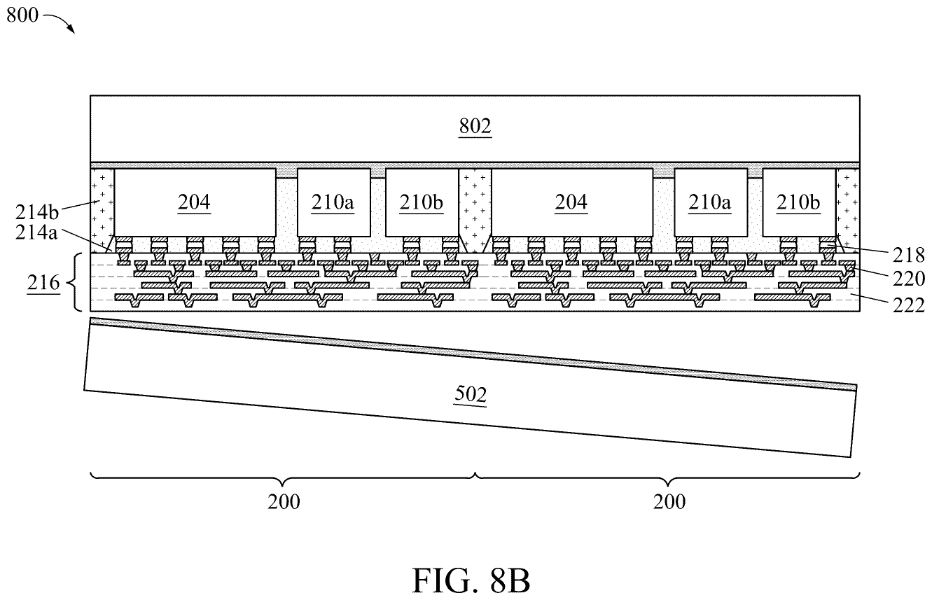

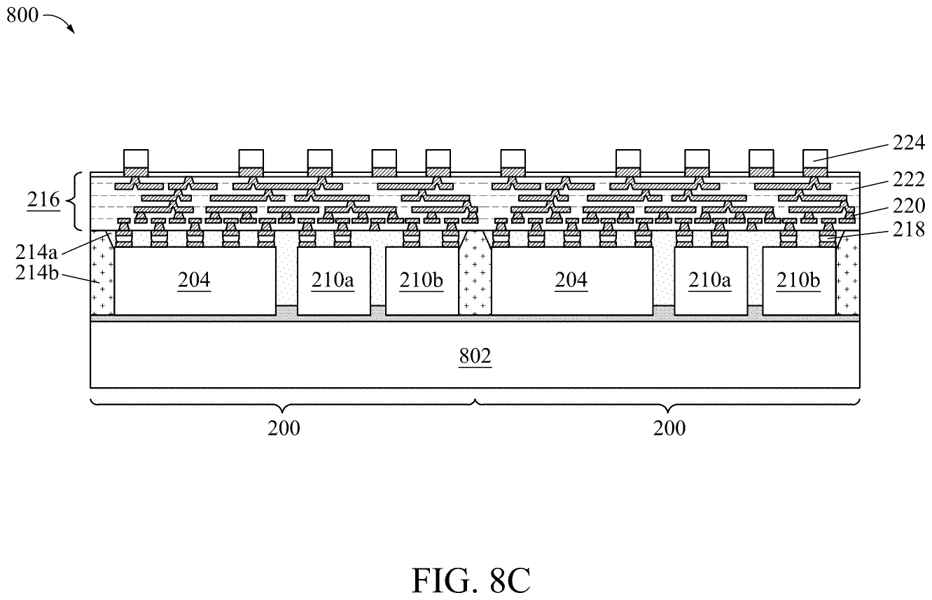

FIGS. 8A-8C are diagrams of an example implementation 800 described herein. The example implementation 800 may include an example of forming the connection structures 224 of multi-die packages 200. In some implementations, one or more of the operations described in connection with FIGS. 8A-8C may be performed after the operations described in connection with the example implementation 500, the example implementation 600, and/or the example implementation 700.

As shown in FIG. 8A, a carrier 802 may be attached to the top surfaces of the dies of the multi-die packages 200. The carrier 802 may be attached using a release layer. The release layer enables the carrier 802 to be subsequently removed.

As shown in FIG. 8B, carrier substrate de-bonding is performed to detach (or “de-bond”) the carrier 502 from the interposer 216. The singulation tool set 125 may de-bond the carrier 502 using one or more techniques, such as projecting a light (e.g., a laser light or an UV light) on a release layer between the carrier 502 and the interposer 216 so that the release layer decomposes under the heat of the light. This enables the carrier 502 to be removed from the interposer 216.

As shown in FIG. 8C, connection structures 224 are formed over and/or on a bottom side of the interposer 216 such that the connection structures 218 and the connection structures 224 are included on opposing sides of the interposer 216. In particular, the connection tool set 115 may form the connection structures 224 over and/or on the bottom-most RDL 220 of the interposer 216. In some implementations, the connection structures 224 include via portions extending into the interposer 216, pad portions on and extending along the top surface of the interposer 216, column portions over the pad portions, and/or other portions. Moreover, the connection structures 224 may include controlled collapse chip connection (C4) bumps, micro bumps, electroless nickel-electroless palladium-immersion gold technique (ENEPIG) formed bumps, and/or another type of conductive structures that are connected to the pad column portions of the connection structures 224. The RDL tool set 105 may form the connection structures 224 in a similar manner and using similar techniques a described above for the connection structures 218.

As indicated above, FIGS. 8A-8C are provided as an example. Other examples may differ from what is described with regard to FIGS. 8A-8C.

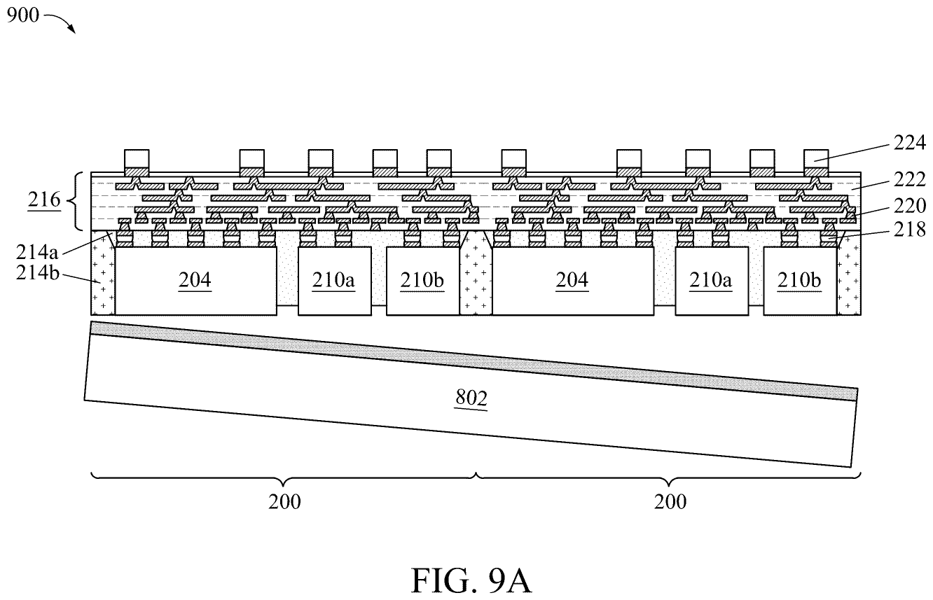

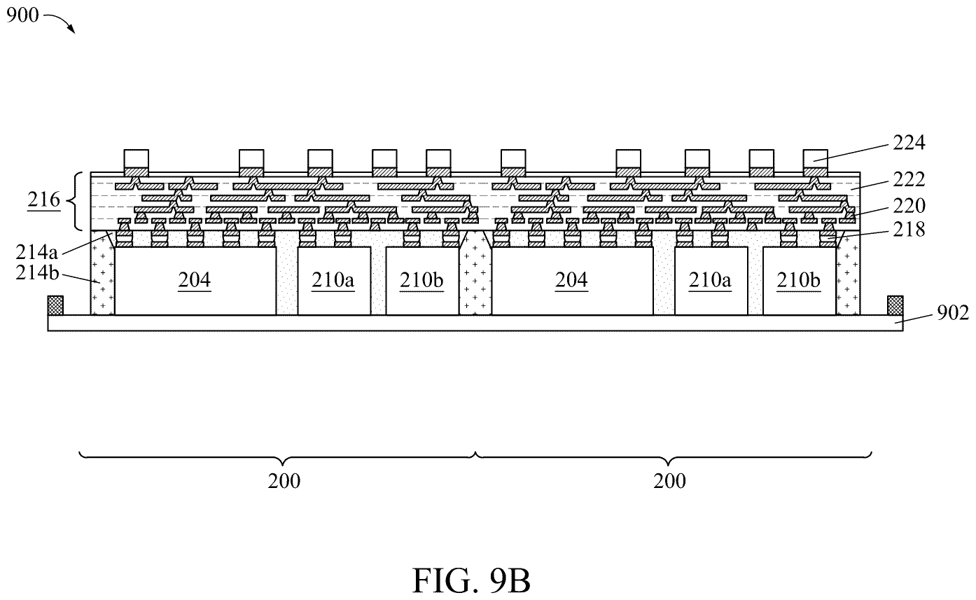

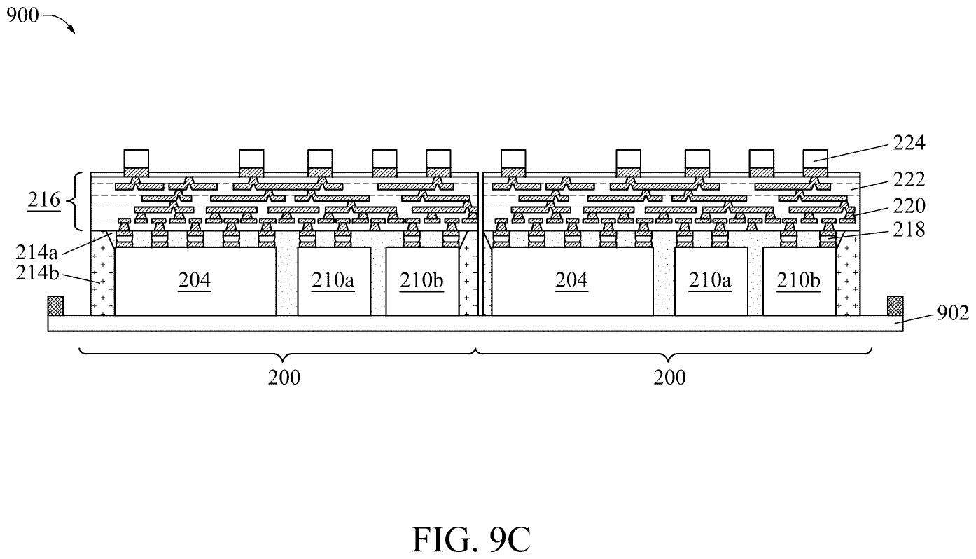

FIGS. 9A-9C are diagrams of an example implementation 900 described herein. The example implementation 900 may include an example of dicing or cutting the multi-die packages 200 into individual pieces. In some implementations, one or more of the operations described in connection with FIGS. 9A-9C may be performed after the operations described in connection with the example implementation 500, the example implementation 600, the example implementation 700, and/or the example implementation 800.

As shown in FIG. 9A, carrier substrate de-bonding is performed to detach (or “de-bond”) the carrier 802 from the dies of the multi-die packages 200. The singulation tool set 125 may de-bond the carrier 802 using one or more techniques, such as projecting a light (e.g., a laser light or an UV light) on a release layer between the carrier 802 and the dies of the multi-die packages 200 so that the release layer decomposes under the heat of the light. This enables the carrier 802 to be removed from the dies of the multi-die packages 200.

As shown in FIG. 9B, the multi-die packages 200 may be attached to a frame 902. The frame 902 may be referred to as a tape frame or another type of frame that supports the multi-die packages 200 during a singulation operation to dice or saw the multi-die packages 200 into individual pieces. In some implementations, the ATE tool set 120 may perform wafer testing on the multi-die packages 200 prior to the singulation operation.

As shown in FIG. 9C, the singulation operation is performed to dice or saw the multi-die packages 200 into individual pieces. The singulation tool set 125 may perform the singulation operation by dicing or sawing along scribe line regions between the multi-die packages 200. The frame 902 may be subsequently removed after the singulation operation.

As indicated above, FIGS. 9A-9C are provided as an example. Other examples may differ from what is described with regard to FIGS. 9A-9C.

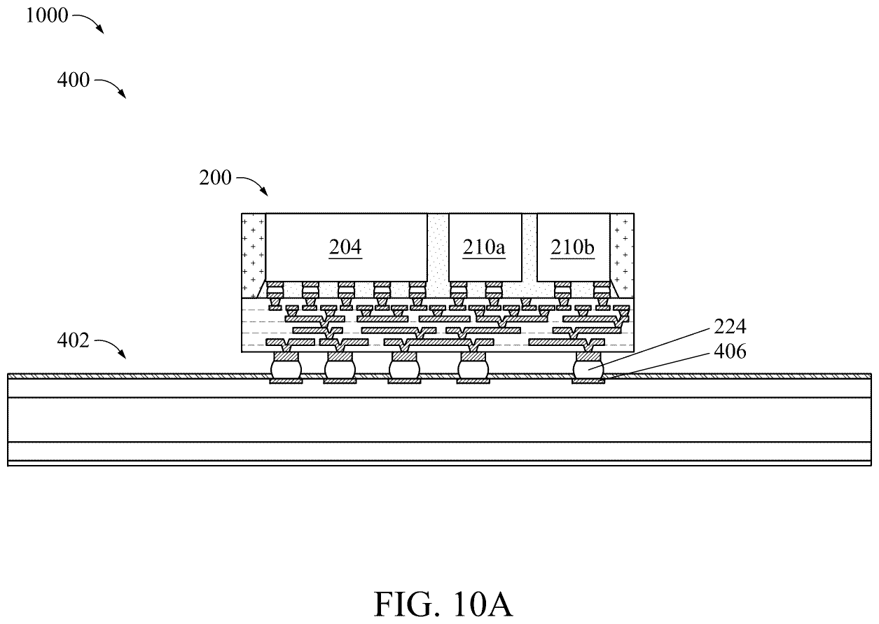

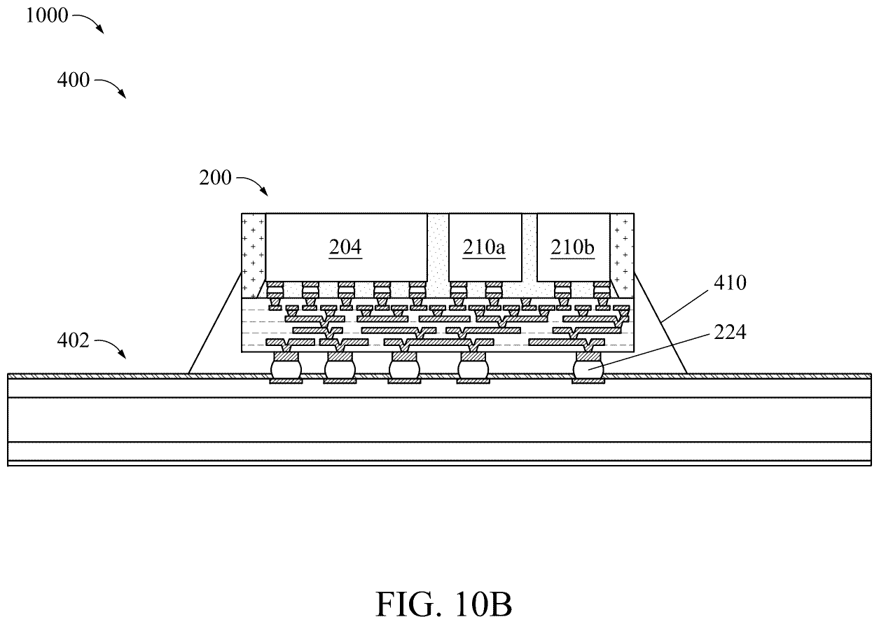

FIGS. 10A and 10B are diagrams of an example implementation 1000 described herein. The example implementation 1000 may include an example of attaching a multi-die package 200 to a device package substrate 402 as part of a process to form a device package 400. In some implementations, one or more of the operations described in connection with FIGS. 10A and 10B may be performed after the operations described in connection with the example implementation 500, the example implementation 600, the example implementation 700, the example implementation 800, and/or the example implementation 900.

As shown in FIG. 10A, the multi-die package 200 may be attached to the device package substrate 402 of the device package 400. The PCB tool set 140 may form the device package substrate 402, and the die-attach tool set 130 may attach the multi-die package 200 to the device package substrate 402. In some implementations, connection structures 224 of the multi-die package 200 are reflowed to attach the multi-die package 200 to conductive structures 406 of the device package substrate 402.

As shown in FIG. 10B, an underfill material 410 may be deposited around the multi-die package 200 above the device package substrate 402. Moreover, the underfill material 410 may be deposited in between and around the connection structures 224. The encapsulation tool set 135 may deposit the underfill material 410 in a capillary flow process, in which the capillary effect is used to deposit the underfill material 410 in between the connection structures 224. Alternatively, another suitable technique may be used to deposit the underfill material 410.

As indicated above, FIGS. 10A and 10B are provided as an example. Other examples may differ from what is described with regard to FIGS. 10A and 10B.

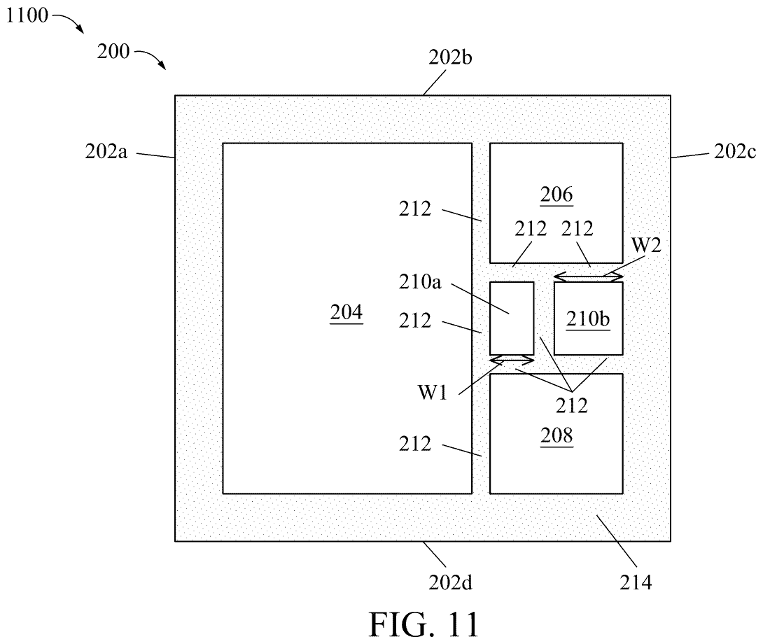

FIG. 11 is a diagram of an example implementation 1100 of a multi-die package 200 described herein. The multi-die package 200 illustrated in the example implementation 1100 may include a similar configuration of structures, dies, and/or layers as the multi-die package 200 illustrated in FIGS. 2A, 2B, and 3. For example, the multi-die package 200 illustrated in the example implementation 1100 may include active IC dies 204-208, non-active dies 210a and 210b, and a filler material 214 surrounding the active IC dies 204-208 and the non-active dies 210a and 210b. However, the non-active dies 210a and 210b in the multi-die package 200 illustrated in the example implementation 1100 have different widths as opposed to approximately the same width. The different widths of the non-active dies 210a and 210b enable flexible placement of gaps 212 in the multi-die package 200, which may increase the uniformity of the distribution of stresses and strains in the multi-die package 200. The increased uniformity of the distribution of stresses and strains in the multi-die package 200 may reduce the magnitude of stress that is experienced in a single gap 212 in the multi-die package 200, which may reduce the likelihood of warpage, cracking, and/or another type of physical damage in the multi-die package 200.

FIG. 11 illustrates a top view of the multi-die package 200 in the example implementation 1100. As shown in FIG. 11, the multi-die package 200 may include a plurality of outer edges that correspond to the perimeter of the multi-die package 200. The plurality of outer edges may include an outer edge 202a, an outer edge 202b, an outer edge 202c, and an outer edge 202d, among other examples. As shown in the example in FIG. 2A, the multi-die package 200 may be approximately square shaped or approximately rectangular shaped. Accordingly, the outer edges 202a and 202c may be located on opposing sides of the multi-die package 200, the outer edges 202b and 202d may be located on opposing sides of the multi-die package 200, the outer edge 202a and 202b may be approximately orthogonal, the outer edge 202a and 202d may be approximately orthogonal, the outer edge 202c and 202b may be approximately orthogonal, and the outer edge 202c and 202d may be approximately orthogonal. However, in other implementations, the multi-die package 200 may be approximately circle shaped (or generally round shaped), hexagon shaped, or another shape. Alternatively, the multi-die package 200 may include a non-standard shape or an amorphous shape.

As further shown in FIG. 11, the multi-die package 200 may include a plurality of active IC dies, such as active IC dies 204-208 for example. The multi-die package 200 may further include non-active dies 210a and 210b. The non-active dies 210a and 210b may be positioned side by side or next to each other (e.g., as opposed to being separated by one or more of the active IC dies 204-208). In other words, the non-active die 210a may be positioned side-by-side with and/or next to the non-active die 210b, and the non-active die 210b may be positioned side-by-side with and/or next to the non-active die 210a.

The non-active die 210a may be positioned closer to the active IC die 204 (and the center of the multi-die package 200) relative to the non-active die 210b, whereas the non-active die 210b may be positioned closer to the outer edge 202c of the multi-die package 200 relative to the non-active die 210a. Accordingly, the non-active dies 210a and 210b may be positioned in a row along a direction between the outer edge 202a and the outer edge 202c, as shown in the example in FIG. 2A. However, in other implementations, the non-active dies 210a and 210b may be positioned in a row along a direction between the outer edge 202b and the outer edge 202d.

As further shown in FIG. 11, the active IC dies 204-208 and the non-active dies 210a and 210b may be spaced apart and/or separated by gaps 212 in the multi-die package 200. For example, the active IC die 204 and the active IC die 206 may be spaced apart and/or separated by a gap 212. As another example, the active IC die 204 and the active IC die 208 may be spaced apart and/or separated by a gap 212. As another example, the active IC die 204 and the non-active die 210a may be spaced apart and/or separated by a gap 212. As another example, the active IC die 206 and the non-active die 210a may be spaced apart and/or separated by a gap 212. As another example, the active IC die 206 and the non-active die 210b may be spaced apart and/or separated by a gap 212. As another example, the active IC die 208 and the non-active die 210a may be spaced apart and/or separated by a gap 212. As another example, the active IC die 208 and the non-active die 210b may be spaced apart and/or separated by a gap 212. As another example, the non-active die 210a and the non-active die 210b may be spaced apart and/or separated by a gap 212.

The gaps 212 may provide physical and/or electrical separation between the active IC dies 204-208 and the non-active dies 210a and 210b. The gaps 212 may be filled with a filler material 214, which may provide additional electrical isolation and/or may provide added rigidity and/or structural integrity for the active IC dies 204-208 and the non-active dies 210a and 210b. The filler material 214 may fill in other areas around the active IC dies 204-208 and the non-active dies 210a and 210b that are not occupied by dies in the multi-die package 200.

The width W1 of the non-active die 210a and the width W2 of the non-active die 210b may be different widths. As an example, the width W2 of the non-active die 210b may be greater relative to the width W1 of the non-active die 210a. This enables the gap 212 between non-active dies 210a and 210b to be positioned closer to the gap 212 between the non-active die 210a and the active IC die 204 than if the non-active dies 210a and 210b were approximately a same width or if the width W1 of the non-active die 210a were greater relative to the width W2 of the non-active die 210b. In some cases, the stresses in the gaps 212 may be more evenly distributed by placing the gap 212 between non-active dies 210a and 210b closer to the gap 212 between the non-active die 210a and the active IC die 204. However, other implementations in which the width W1 of the non-active die 210a is greater relative to the width W2 of the non-active die 210b are within the scope of the present disclosure.

In some implementations, a ratio of the width W2 of the non-active die 210b to the width W1 of the non-active die 210a is included in a range of greater than 1:1 to less than or approximately 10:1 to ensure that the width W2 is greater than the width W1 for increased stress distribution uniformity and to ensure that the size of the non-active die 210a is sufficiently large to enable placement by the die attach tool set 130. However, other values for the range are within the scope of the present disclosure.

As indicated above, FIG. 11 is provided as an example. Other examples may differ from what is described with regard to FIG. 11.

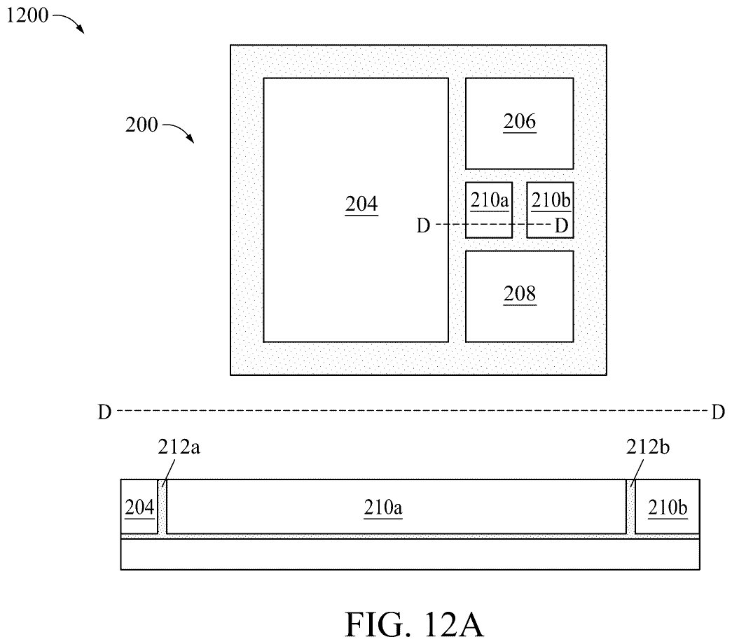

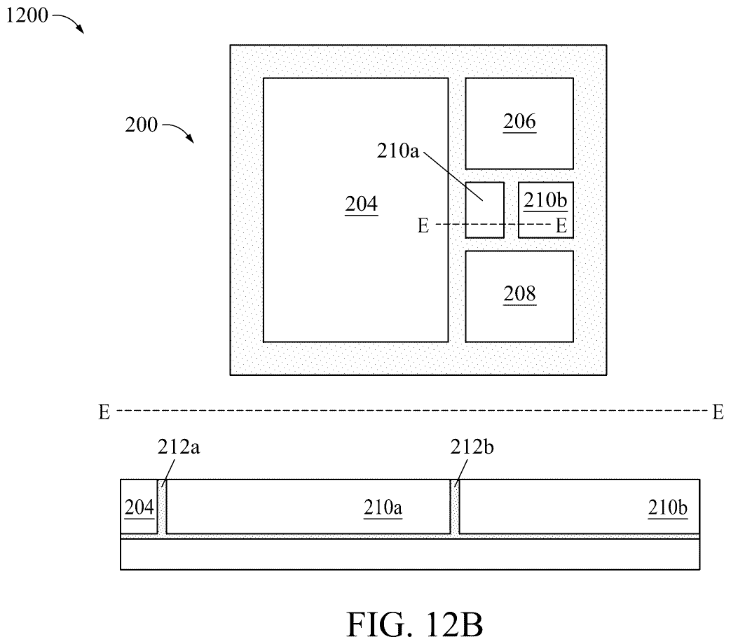

FIGS. 12A and 12B are diagrams of example implementations 1200 described herein. The example implementations 1200 include examples of magnitudes of stresses that are experienced in gaps 212 between dies in a multi-die package 200 described herein.

FIG. 12A illustrates an example of magnitudes of stresses that are experienced in a gap 212a between an active IC die 204 and an adjacent non-active die 210a, and in a gap 212b between the non-active die 210a and an adjacent non-active die 210b. A top-down view of the multi-die package 200 is illustrated in an upper portion of FIG. 12A, and a cross-section view along the line D-D is illustrated in the lower portion of FIG. 12A. In this example, the widths of the non-active dies 210a are approximately equal.

In the example in FIG. 12A, the magnitude of the stress experienced in the gap 212a is greater relative to the stress experienced in the gap 212b. However, the magnitudes of the stresses experienced in the gaps 212a and 212b may both be lesser than if the gap 212 were omitted such that only a single gap 212a were included between the active IC die 204 and a single non-active die.

FIG. 12B illustrates an example of magnitudes of stresses that are experienced in a gap 212a between an active IC die 204 and an adjacent non-active die 210a, and in a gap 212b between the non-active die 210a and an adjacent non-active die 210b. A top-down view of the multi-die package 200 is illustrated in an upper portion of FIG. 12B, and a cross-section view along the line E-E is illustrated in the lower portion of FIG. 12B. In this example, the widths of the non-active dies 210a and 210b are different. In particular, the width W2 of the non-active die 210b is greater relative to the width W1 of the non-active die 210a. This results in the gap 212b being positioned closer to the gap 212a and closer to the active IC die 204.

In the example in FIG. 12B, the widths of the non-active dies 210a and 210b may be configured such that the magnitude of the stresses experienced in the gaps 212a and 212b are approximately equal. The magnitudes of the stresses experienced in the gaps 212a and 212b may both be lesser than if the gap 212 were omitted such that only a single gap 212a were included between the active IC die 204 and a single non-active die.

As indicated above, FIGS. 12A and 12B are provided as examples. Other examples may differ from what is described with regard to FIGS. 12A and 12B.

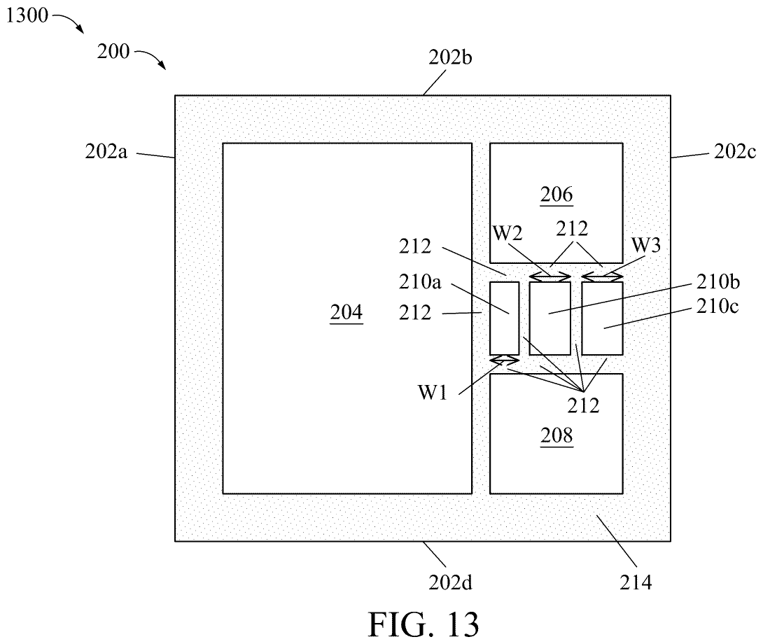

FIG. 13 is a diagram of an example implementation 1300 of a multi-die package 200 described herein. The multi-die package 200 illustrated in the example implementation 1300 may include a similar configuration of structures, dies, and/or layers as the multi-die package 200 illustrated in FIGS. 2A, 2B, and 3. For example, the multi-die package 200 illustrated in the example implementation 1300 may include active IC dies 204-208, non-active dies 210a and 210b, and a filler material 214 surrounding the active IC dies 204-208 and the non-active dies 210a and 210b. However, the non-active dies 210a and 210b in the multi-die package 200 illustrated in the example implementation 1300 have different widths as opposed to approximately the same width. Moreover, the multi-die package 200 illustrated in the example implementation 1300 includes at least one additional non-active die (e.g., a non-active die 210c). The combination of the additional nonactive die(s) and different widths of the non-active dies enable flexible placement of gaps 212 in the multi-die package 200, which may increase the uniformity of the distribution of stresses and strains in the multi-die package 200. The increased uniformity of the distribution of stresses and strains in the multi-die package 200 may reduce the magnitude of stress that is experienced in a single gap 212 in the multi-die package 200, which may reduce the likelihood of warpage, cracking, and/or another type of physical damage in the multi-die package 200.

As shown in FIG. 13, the multi-die package 200 in the example implementation 1300 includes the active IC dies 204-208. The multi-die package 200 in the example implementation 1300 includes the non-active die 210b, which may be positioned between two or more of the active IC dies 204-208. The multi-die package 200 in the example implementation 1300 includes the non-active die 210a, which may be positioned next to a first side of the non-active die 210b and between the two or more of the active IC dies 204-208. The multi-die package 200 in the example implementation 1300 includes the non-active die 210c, which may be positioned next to a second side of the non-active die 210b opposing the first side, and between the two or more of the active IC dies 204-208. The non-active dies 210a-210c may be arranged in a row such that the non-active die 210a is positioned closed to the center of the multi-die package 200 (and closes to the active IC die 204), such that the non-active die 210c is positioned closes to an outer edge 202c of the multi-die package 200, and such that the non-active die 210b is positioned between the non-active die 210a and the non-active die 210c. The non-active dies 210a-210c may be separated by gaps 212, which may be filled with a filler material 214. The quantity of non-active dies illustrated in FIG. 13 is an example, and other quantities of non-active dies are within the scope of the present disclosure.

In some implementations, first respective edges of the non-active dies 210a-210c adjacent to or next to the active IC die 206 may be approximately aligned in the multi-die package 200. In some implementations, second respective edges of the non-active dies 210a-210c adjacent to or next to the active IC die 208 may be approximately aligned in the multi-die package 200. Accordingly, the lengths L1 (illustrated in FIG. 3) of the non-active dies 210a-210c may be approximately a same length.

The non-active die 210a may include a width W1, the non-active die 210b may include a width W2, and the non-active die 210c may include a width W3. In some implementations, the widths W1-W3 are approximately equal. In some implementations, two or more of the widths W1-W3 are different widths. As described above, the width W2 of the non-active die 210b may be greater relative to the width W1 of the non-active die 210a. In some implementations, the width W3 of the non-active die 210c is also greater relative to the width W1 of the non-active die 210a. In some implementations, the width W2 of the non-active die 210b is greater relative to the width W3 of the non-active die 210c. In some implementations, the width W3 of the non-active die 210c is greater relative to the width W2 of the non-active die 210b.

In some implementations, a ratio of the width W3 of the non-active die 210c to the width W1 of the non-active die 210a is included in a range of greater than 1:1 to less than or approximately 10:1 to ensure that the width W3 is greater than the width W1 for increased stress distribution uniformity and to ensure that the size of the non-active die 210a is sufficiently large to enable placement by the die attach tool set 130. However, other values for the range are within the scope of the present disclosure.

As indicated above, FIG. 13 is provided as an example. Other examples may differ from what is described with regard to FIG. 13.

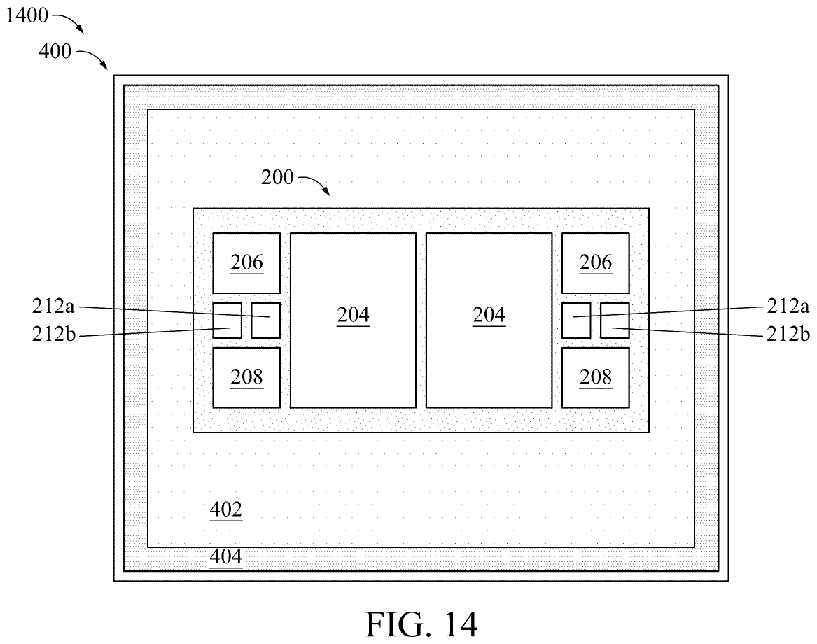

FIG. 14 is a diagram of an example implementation 1400 of a device package 400 described herein. The device package 400 of the example implementation 1400 may be similar to, and may include a similar configuration of structures, components, and/or layers as, the device package 400 illustrated and described in connection with FIGS. 4A and 4B. However, the multi-die package 200 in the device package 400 of the example implementation 1400 includes a multi-logic IC multi-die package 200. As shown in FIG. 14, the multi-die package 200 includes a plurality of active IC dies 204, a plurality of active IC dies 206, a plurality of active IC dies 208, a plurality of non-active dies 210a, and a plurality of non-active dies 210b. The quantity of active dies and non-active dies illustrated in FIG. 14 is an example, and other quantities of active IC dies and non-active dies are within the scope of the present disclosure.

As shown in FIG. 14, sets of dies including an active IC die 204, an active IC die 206, an active IC die 208, a non-active die 210a, and a non-active die 210b may be grouped together on the multi-die package 200. The sets of dies may include mirrored arrangements as shown in FIG. 14, may include a non-mirrored (e.g., a duplicated arrangement), and/or another type of arrangement in the multi-die package. The active IC dies 204 may be positioned at or near the center of the multi-die package 200, and the active IC dies 206, the active IC dies 208, the non-active dies 210a, and the non-active dies 210b may be positioned at or near the outer edges of the device package substrate 402 (near the stiffener structure 404) of the device package 400. Alternatively, the active IC dies 206, the active IC dies 208, the non-active dies 210a, and the non-active dies 210b may be positioned at or near the center of the multi-die package 200, and the active IC dies 204 may be positioned at or near the outer edges of the device package substrate 402 (near the stiffener structure 404) of the device package 400.

As indicated above, FIG. 14 is provided as an example. Other examples may differ from what is described with regard to FIG. 14.

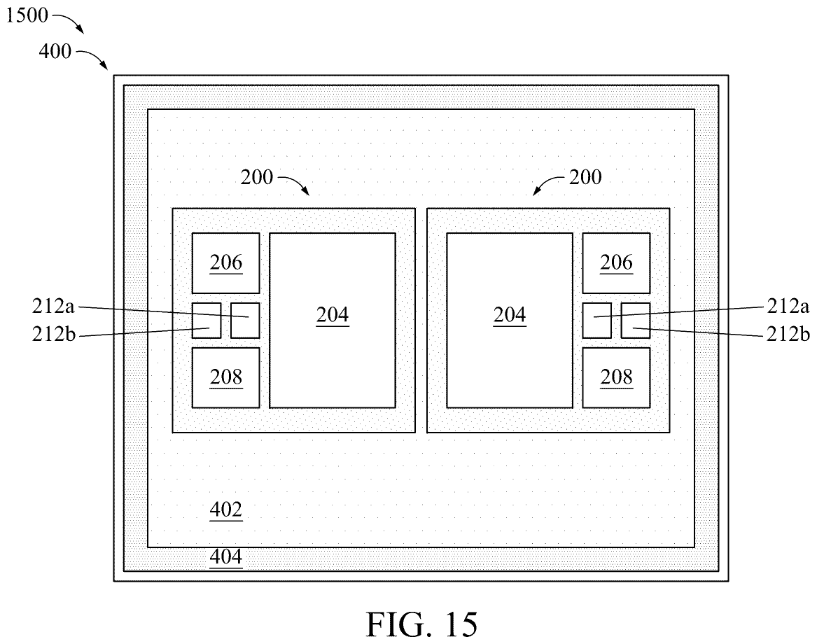

FIG. 15 is a diagram of an example implementation 1500 of a device package 400 described herein. The device package 400 of the example implementation 1500 may be similar to the device package 400 of the example implementation 1400. However, the sets of sides are included in different multi-die packages 200 such that the device package 400 of the example implementation 1500 includes a plurality of multi-die packages 200.

As indicated above, FIG. 15 is provided as an example. Other examples may differ from what is described with regard to FIG. 15.

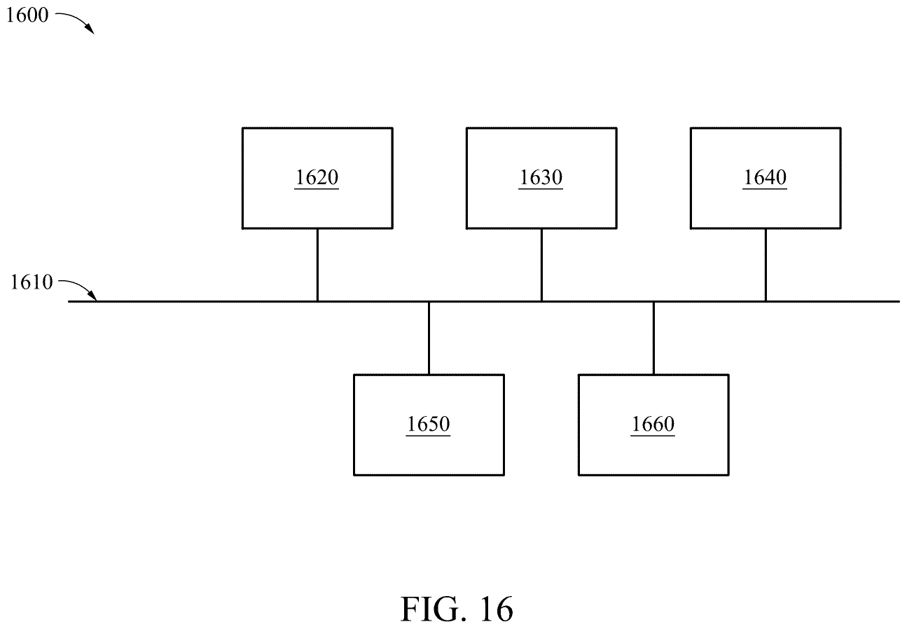

FIG. 16 is a diagram of example components of a device 1600. In some implementations, one or more of the semiconductor processing tool sets 105-150 and/or the transport tool set 155 may include one or more devices 1600 and/or one or more components of device 1600. As shown in FIG. 16, device 1600 may include a bus 1610, a processor 1620, a memory 1630, an input component 1640, an output component 1650, and a communication component 1660.

Bus 1610 includes one or more components that enable wired and/or wireless communication among the components of device 1600. Bus 1610 may couple together two or more components of FIG. 16, such as via operative coupling, communicative coupling, electronic coupling, and/or electric coupling. Processor 1620 includes a central processing unit, a graphics processing unit, a microprocessor, a controller, a microcontroller, a digital signal processor, a field-programmable gate array, an application-specific integrated circuit, and/or another type of processing component. Processor 1620 is implemented in hardware, firmware, or a combination of hardware and software. In some implementations, processor 1620 includes one or more processors capable of being programmed to perform one or more operations or processes described elsewhere herein.

Memory 1630 includes volatile and/or nonvolatile memory. For example, memory 1630 may include random access memory (RAM), read only memory (ROM), a hard disk drive, and/or another type of memory (e.g., a flash memory, a magnetic memory, and/or an optical memory). Memory 1630 may include internal memory (e.g., RAM, ROM, or a hard disk drive) and/or removable memory (e.g., removable via a universal serial bus connection). Memory 1630 may be a non-transitory computer-readable medium. Memory 1630 stores information, instructions, and/or software (e.g., one or more software applications) related to the operation of device 1600. In some implementations, memory 1630 includes one or more memories that are coupled to one or more processors (e.g., processor 1620), such as via bus 1610.

Input component 1640 enables device 1600 to receive input, such as user input and/or sensed input. For example, input component 1640 may include a touch screen, a keyboard, a keypad, a mouse, a button, a microphone, a switch, a sensor, a global positioning system sensor, an accelerometer, a gyroscope, and/or an actuator. Output component 1650 enables device 1600 to provide output, such as via a display, a speaker, and/or a light-emitting diode. Communication component 1660 enables device 1600 to communicate with other devices via a wired connection and/or a wireless connection. For example, communication component 1660 may include a receiver, a transmitter, a transceiver, a modem, a network interface card, and/or an antenna.

Device 1600 may perform one or more operations or processes described herein. For example, a non-transitory computer-readable medium (e.g., memory 1630) may store a set of instructions (e.g., one or more instructions or code) for execution by processor 1620. Processor 1620 may execute the set of instructions to perform one or more operations or processes described herein. In some implementations, execution of the set of instructions, by one or more processors 1620, causes the one or more processors 1620 and/or the device 1600 to perform one or more operations or processes described herein. In some implementations, hardwired circuitry is used instead of or in combination with the instructions to perform one or more operations or processes described herein. Additionally, or alternatively, processor 1620 may be configured to perform one or more operations or processes described herein. Thus, implementations described herein are not limited to any specific combination of hardware circuitry and software.

The number and arrangement of components shown in FIG. 16 are provided as an example. Device 1600 may include additional components, fewer components, different components, or differently arranged components than those shown in FIG. 16. Additionally, or alternatively, a set of components (e.g., one or more components) of device 1600 may perform one or more functions described as being performed by another set of components of device 1600.

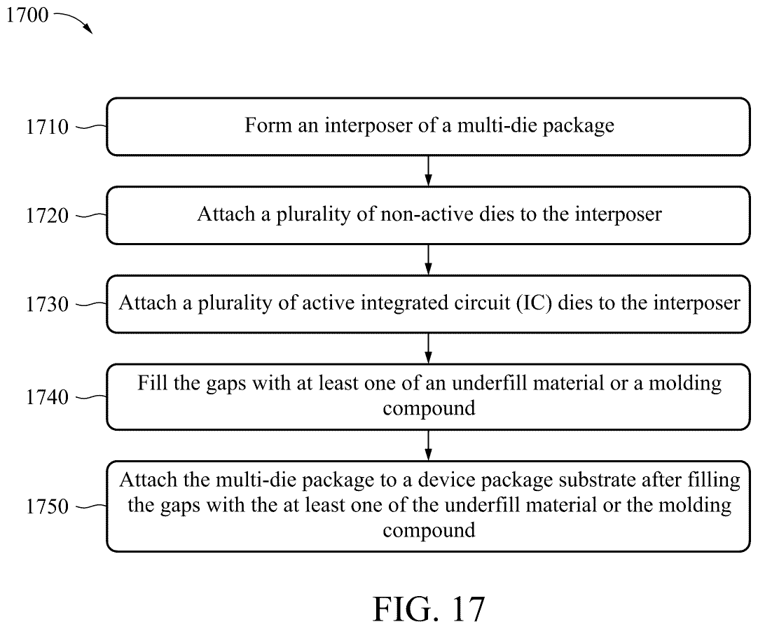

FIG. 17 is a flowchart of an example process 1700 associated with forming a device package. In some implementations, one or more process blocks of FIG. 17 are performed by one or more semiconductor processing tool sets (e.g., one or more of the semiconductor processing tool sets 105-150). Additionally, or alternatively, one or more process blocks of FIG. 17 may be performed by one or more components of device 1600, such as processor 1620, memory 1630, input component 1640, output component 1650, and/or communication component 1660.

As shown in FIG. 17, process 1700 may include forming an interposer of a multi-die package (block 1710). For example, one or more of the semiconductor processing tool sets 105-150 may form an interposer 216 of a multi-die package 200, as described above. In some implementations, the interposer 216 includes a plurality of redistribution layers 220.

As further shown in FIG. 17, process 1700 may include attaching a plurality of non-active dies to the interposer (block 1720). For example, one or more of the semiconductor processing tool sets 105-150 may attach a plurality of non-active dies 210a-210c to the interposer 216, as described above.

As further shown in FIG. 17, process 1700 may include attaching a plurality of active IC dies to the interposer (block 1730). For example, one or more of the semiconductor processing tool sets 105-150 may attach a plurality of active IC dies 204-208 to the interposer 216, as described above. In some implementations, the plurality of non-active dies 210a-210c are arranged side by side in a row on the interposer 216 such that the plurality of non-active dies 210a-210c and the plurality of active IC 204-208 dies are spaced apart by gaps 212.

As further shown in FIG. 17, process 1700 may include filling the gaps with at least one of an underfill material or a molding compound (block 1740). For example, one or more of the semiconductor processing tool sets 105-150 may fill the gaps 212 with at least one of an underfill material 214a or a molding compound (e.g., an encapsulant material 214b), as described above.

As further shown in FIG. 17, process 1700 may include attaching the multi-die package to a device package substrate after filling the gaps with the at least one of the underfill material or the molding compound (block 1750). For example, one or more of the semiconductor processing tool sets 105-150 may attach the multi-die package 200 to a device package substrate 402 after filling the gaps 212 with the at least one of the underfill material 214a or the molding compound (e.g., an encapsulant material 214b), as described above.

Process 1700 may include additional implementations, such as any single implementation or any combination of implementations described below and/or in connection with one or more other processes described elsewhere herein.

In a first implementation, the multi-die package 200 is a first multi-die package 200, and process 1700 includes forming another interposer 216 of a second multi-die package 200, where the other interposer 216 of the second multi-die package 200 includes another plurality of redistribution layers 220, attaching another plurality of non-active dies 210a-210c to the other interposer 216 of the second multi-die package 200, attaching another plurality of active IC dies 204-208 to the other interposer 216 of the second multi-die package 200, where the other plurality of non-active dies 210a-210c are arranged side by side in a row on the other interposer 216 such that the other plurality of non-active dies 210a-210c and the other plurality of active IC dies 204-208 are spaced apart by other gaps 212, filling the other gaps 212 with at least one of another underfill material 214a or another molding compound (e.g., an encapsulant material 214b), and attaching the second multi-die package 200 to the device package substrate 402 after filling the other gaps 212 with the at least one of the other underfill material 214a or the other molding compound (e.g., an encapsulant material 214b).

In a second implementation, alone or in combination with the first implementation, the plurality of non-active dies 210a-210c include a first non-active die 210a, and a second non-active die 210b side-by-side with the first non-active die 210a, the second non-active die 210b being positioned closer to an outer edge 202c of the multi-die package 200 relative to the first non-active die 210a, and a ratio of a width W2 of the second non-active die 210b to a width W1 of the first non-active die 210a is included in a range of greater than 1:1 to less than or approximately equal to 10:1.

In a third implementation, alone or in combination with one or more of the first and second implementations, the plurality of non-active dies 210a-210c include a third non-active die 210c side-by-side with the second non-active die 210b, the third non-active die 210c being positioned closer to the outer edge 202c of the multi-die package 200 relative to the second non-active die 210b, and a ratio of a width W3 of the third non-active die 210c to the width W1 of the first non-active 210a die is included in a range of greater than 1:1 to less than or approximately equal to 10:1.

In a fourth implementation, alone or in combination with one or more of the first through third implementations, respective first edges of the first non-active die 210a and the second non-active die 210b are approximately aligned and are adjacent to a first active IC die 206 of the plurality of active IC dies 204-208, and respective second edges of the first non-active die 210a and the second non-active die 210b, that are opposing the respective first edges, are approximately aligned and are adjacent to a second active IC die 208 of the plurality of active IC dies 204-208.

In a fifth implementation, alone or in combination with one or more of the first through fourth implementations, a third edge of the first non-active die 210a, that is approximately orthogonal to the respective first edges and the respective second edges, is adjacent to a third active IC die 204 of the plurality of active IC dies 204-208.

Although FIG. 17 shows example blocks of process 1700, in some implementations, process 1700 includes additional blocks, fewer blocks, different blocks, or differently arranged blocks than those depicted in FIG. 17. Additionally, or alternatively, two or more of the blocks of process 1700 may be performed in parallel.

In this way, a multi-die package includes a plurality of non-active dies among the IC dies included in the multi-die package. The non-active dies may be included to reduce the amount of encapsulant material and/or an underfill material that is used in the multi-die package, which reduces the amount of CTE mismatch in the multi-die package. Moreover, a plurality of non-active dies may be positioned in an adjacent manner between two or more active IC dies. The use of a plurality of non-active dies in a particular area of the multi-die package increases the quantity of gaps in the multi-die package as opposed to the use of a single non-active die in the particular area. The increased quantity of gaps in the multi-die package provides an increased amount of area in the multi-die package for stress and strain absorption, and enables more even distribution of stresses and strains in the multi-die package relative to the use of a single non-active die in the particular area. Accordingly, the use of a plurality of non-active dies in a particular area of the multi-die package may reduce the amount of CTE mismatching in the multi-die package, which may reduce the likelihood of warpage, bending, and/or cracking in the multi-die package. The reduced likelihood of warpage, bending, and/or cracking in the multi-die package may reduce the likelihood of failure of the multi-die package and/or may reduce the likelihood of failure of one or more IC dies included therein, which may increase multi-die package yield.

As described in greater detail above, some implementations described herein provide a multi-die package. The multi-die package includes a plurality of active IC dies attached to an interposer. The multi-die package includes a plurality of side-by-side non-active dies that are positioned between two or more of the plurality of active IC dies and attached to the interposer.

As described in greater detail above, some implementations described herein provide a multi-die package. The multi-die package includes a plurality of active IC dies attached to an interposer. The multi-die package includes a first non-active die attached to the interposer, where the first non-active die is positioned between two or more of the plurality of active IC dies. The multi-die package includes a second non-active die attached to the interposer, where the second non-active die is positioned next to a first side of the first non-active die, and is positioned between the two or more of the plurality of active IC dies. The multi-die package includes a third non-active die attached to the interposer, where the third non-active die is positioned next to a second side of the first non-active die opposing the first side, and is positioned between the two or more of the plurality of active IC dies.

As described in greater detail above, some implementations described herein provide a method. The method includes forming an interposer of a multi-die package, where the interposer includes a plurality of redistribution layers. The method includes attaching a plurality of non-active dies to the interposer. The method includes attaching a plurality of active IC dies to the interposer, where the plurality of non-active dies are arranged side by side in a row on the interposer such that the plurality of non-active dies and the plurality of active IC dies are spaced apart by gaps. The method includes filling the gaps with at least one of an underfill material or a molding compound. The method includes attaching the multi-die package to a device package substrate after filling the gaps with the at least one of the underfill material or the molding compound.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming an interposer of a multi-die package,
wherein the interposer comprises a plurality of redistribution layers;
attaching a plurality of non-active dies to the interposer;
attaching a plurality of active integrated circuit (IC) dies to the interposer,
wherein the plurality of non-active dies are arranged side by side in a row on the interposer such that the plurality of non-active dies and the plurality of active IC dies are spaced apart by first gaps;
filling the first gaps with at least one of an underfill material or a molding compound; and
attaching the multi-die package to a device package substrate after filling the first gaps with the at least one of the underfill material or the molding compound.

2. The method of claim 1, wherein the multi-die package is a first multi-die package; and
wherein the method further comprises:
forming another interposer of a second multi-die package,
wherein the other interposer of the second multi-die package comprises another plurality of redistribution layers;
attaching another plurality of active IC dies to the other interposer of the second multi-die package;
attaching another plurality of non-active dies to the other interposer of the second multi-die package,
wherein the other plurality of non-active dies are arranged side by side in a row on the other interposer such that the other plurality of non-active dies and the other plurality of active IC dies are spaced apart by second gaps;
filling the second gaps with at least one of another underfill material or another molding compound; and
attaching the second multi-die package to the device package substrate after filling the second gaps with the at least one of the other underfill material or the other molding compound.

3. The method of claim 1, wherein the plurality of non-active dies comprise:
a first non-active die; and
a second non-active die side-by-side with the first non-active die,
wherein the second non-active die is positioned closer to an outer edge of the multi-die package relative to the first non-active die, and
wherein a ratio of a width of the second non-active die to a width of the first non-active die is included in a range of greater than 1:1 to less than or approximately equal to 10:1.

4. The method of claim 3, wherein the plurality of non-active dies comprise:
a third non-active die side-by-side with the second non-active die,
wherein the third non-active die is positioned closer to the outer edge of the multi-die package relative to the second non-active die, and
wherein a ratio of a width of the third non-active die to the width of the first non-active die is included in a range of greater than 1:1 to less than or approximately equal to 10:1.

5. The method of claim 3, wherein respective first edges of the first non-active die and the second non-active die are approximately aligned and are adjacent to a first active IC die of the plurality of active IC dies; and
wherein respective second edges of the first non-active die and the second non-active die, that are opposing the respective first edges, are approximately aligned and are adjacent to a second active IC die of the plurality of active IC dies.

6. The method of claim 5, wherein a third edge of the first non-active die, that is approximately orthogonal to the respective first edges and the respective second edges, is adjacent to a third active IC die of the plurality of active IC dies.

7. A method, comprising:
attaching a plurality of active integrated circuit (IC) dies to an interposer of a multi-die package; and
attaching a plurality of side-by-side non-active dies to the interposer, wherein the plurality of side-by-side non-active dies are positioned between two or more of the plurality of active IC dies.

8. The method of claim 7, further comprising:
filling, with an underfill material, at least one of:
first gaps between the plurality of active IC dies,
second gaps between the plurality of side-by-side non-active dies, or
third gaps between the plurality of side-by-side non-active dies and the plurality of active IC dies.

9. The method of claim 7, wherein the plurality of side-by-side non-active dies comprise:
a first non-active die, and
a second non-active die side-by-side with the first non-active die,
wherein the second non-active die is positioned closer to an outer edge of the multi-die package relative to the first non-active die.

10. The method of claim 9, wherein a width of the second non-active die is greater relative to a width of the first non-active die.

11. The method of claim 9, wherein a length of the first non-active die and a length of the second non-active die are approximately a same length.

12. The method of claim 9, wherein a width of a gap between the first non-active die and an active IC die, of the plurality of active IC dies, adjacent to the first non-active die is included in a range of approximately 50 microns to approximately 200 microns.

13. The method of claim 7, wherein the plurality of side-by-side non-active dies comprise at least one of:
a dummy die, or
an integrated passive device (IPD).

14. The method of claim 7, wherein the plurality of active IC dies are a first plurality of active IC dies in the multi-die package,
wherein the plurality of side-by-side non-active dies is a first plurality of side-by-side non-active dies in the multi-die package, and
wherein the multi-die package further comprises:
a second plurality of active IC dies attached to the interposer, and
a second plurality of side-by-side non-active dies that are positioned between two or more of the second plurality of active IC dies and attached to the interposer.

15. A method, comprising:
attaching a plurality of active integrated circuit (IC) dies to an interposer of a multi-die package; and
attaching a plurality of non-active dies, to the interposer, comprising:
a first non-active die between two or more of the plurality of active IC dies,
a second non-active die adjacent to a first side, of the first non-active die, and between the two or more of the plurality of active IC dies, and
a third non-active die adjacent to a second side, of the first non-active die and opposing the first side, and between the two or more of the plurality of active IC dies.

16. The method of claim 15, wherein first respective edges of the first non-active die, the second non-active die, and the third non-active die are approximately aligned in the multi-die package, and
wherein second respective edges of the first non-active die, the second non-active die, and the third non-active die, opposing the first respective edges, are approximately aligned in the multi-die package.

17. The method of claim 15, wherein a width of the first non-active die is greater relative to a width of the second non-active die, and
wherein the width of the third non-active die is greater relative to the width of the second non-active die.

18. The method of claim 17, wherein the width of the first non-active die is greater relative to a width of the third non-active die.

19. The method of claim 18, wherein the width of the third non-active die is greater relative to the width of the second non-active die.

20. The method of claim 15, wherein the second non-active die is positioned closer to a center of the multi-die package relative to the first non-active die and relative to the third non-active die,
wherein the third non-active die is positioned closer to an outer edge of the multi-die package relative to the first non-active die and relative to the second non-active die, and
wherein the first non-active die is positioned between the second non-active die and the third non-active die.
